(19) United States
(12) Patent Application Publication
(10) Pub. No.: US 2020/0098831 A1
(43) Pub. Date: Mar. 26, 2020

(54) ORGANIC ELECTROLUMINESCENCE ELEMENT, ORGANIC ELECTROLUMINESCENCE PANEL AND ELECTRONIC APPARATUS

(71) Applicant: JOLED Inc., Tokyo (JP)

(72) Inventor: Hideyuki SHIRAHASE, Tokyo (JP)

(73) Assignee: JOLED Inc., Tokyo (JP)

(21) Appl. No.: 16/554,626

(22) Filed: Aug. 29, 2019

(30) Foreign Application Priority Data
Sep. 20, 2018 (JP) 2018-175874
May 14, 2019 (JP) 2019-091166

(51) Int. Cl. H01L 27/32; H01L 51/52; H01L 51/50

(52) U.S. Cl. CPC H01L 27/3206; H01L 51/5221; G09G 3/3233; H01L 51/5092; H01L 51/5218; H01L 51/5072

(57) ABSTRACT

Disclosed is an organic electroluminescence element including: an anode, a light emitting layer and a cathode in this order; and a low refractive index layer lower in refractive index than the light emitting layer at at least one of a position between the light emitting layer and the cathode and a position between the anode and the light emitting layer.

### CROSS-REFERENCE TO RELATED APPLICATIONS

The present application claims priority to JP 2018-175874, filed on Sep. 20, 2018, and JP 2019-091166, filed on May 14, 2019, the entire contents of each are incorporated herein by reference.

### BACKGROUND

The present disclosure relates to an organic electroluminescence element, an organic electroluminescence panel and an electronic apparatus.

As an organic electroluminescence device (organic electroluminescence display) using organic electroluminescence elements, a variety of ones have been proposed (see, for example, JP 2017-072812A).

### SUMMARY

Meanwhile, in an organic electroluminescence device, in general, it is demanded to enhance the light extraction efficiency of organic electroluminescence elements. Therefore, it is desirable to provide an organic electroluminescence element capable of enhancing light extraction efficiency, and an organic electroluminescence panel and an electronic apparatus that include such organic electroluminescence elements.

According to an embodiment of the present disclosure, there is provided an organic electroluminescence element including an anode, a light emitting layer and a cathode in this order, and a low refractive index layer lower in refractive index than the light emitting layer at at least one of a position between the light emitting layer and the cathode and a position between the anode and the light emitting layer.

According to another embodiment of the present disclosure, there is provided an organic electroluminescence panel that includes a plurality of pixels. Each of the pixels has the above-mentioned organic electroluminescence element.

According to a further embodiment of the present disclosure, there is provided an electronic apparatus including the above-mentioned organic electroluminescence panel, and a driving circuit that drives the organic electroluminescence panel.

In the organic electroluminescence element, the organic electroluminescence panel and the electronic apparatus according to the embodiments of the present disclosure, the low refractive index layer lower in refractive index than the light emitting layer is provided at at least one of a position between the light emitting layer and the cathode and a position between the anode and the light emitting layer. This ensures that to the light going from the light emitting layer toward the low refractive index layer, the critical angle at the interface of the low refractive index layer is reduced. Therefore, the proportion in which the light going from the light emitting layer toward the low refractive index layer is reflected at the interface of the low refractive index layer is enhanced as compared to the case where the low refractive index layer is not provided. As a result, the proportion of evanescent deactivation due, for example, to surface plasmon at the anode and in the vicinity of the anode (evanescent mode) is lowered, and, therefore, the proportions of an external release mode and a waveguide mode are increased.

In accordance with the organic electroluminescence element, the organic electroluminescence panel and the electronic apparatus of the embodiments of the present disclosure, the low refractive index layer lower in refractive index than the light emitting layer is provided at at least one of a position between the light emitting layer and the cathode and a position between the anode and the light emitting layer, and, therefore, the proportions of the external release mode and the waveguide mode can be increased. As a result, light extraction efficiency can be enhanced. Note that the effects of the present disclosure are not limited to the effect described here, and the present disclosure may have any of the effects described herein.

### BRIEF DESCRIPTION OF THE DRAWINGS

FIG. 1 is a figure depicting a sectional configuration example of an organic electroluminescence element according to a first embodiment of the present disclosure;

FIG. 2A depicts an example of mode ratio of propagation mode of energy generated in an organic electroluminescence element according to a comparative example, and FIG. 2B depicts a configuration example of propagation mode of energy generated in an organic electroluminescence element according to a working example;

FIG. 3 depicts an example of the relation between refractive index of a low refractive index layer and mode ratio of propagation mode, in an organic electroluminescence element that emits red light;

FIG. 4 depicts an example of the relation between refractive index of a low refractive index layer and mode ratio of propagation mode, in an organic electroluminescence element that emits green light;

FIG. 5 depicts an example of the relation between refractive index of a low refractive index layer and mode ratio of propagation mode, in an organic electroluminescence element that emits blue light;

FIG. 6A depicts an example of mode ratio of propagation mode of energy generated in an organic electroluminescence element according to a comparative example, and FIG. 6B depicts a configuration example of propagation mode of energy generated in an organic electroluminescence element according to a working example;

FIG. 7 depicts an example of the relation between refractive index of a low refractive index layer and mode ratio of propagation mode, in an organic electroluminescence element that emits red light;

FIG. 8 depicts an example of the relation between refractive index of a low refractive index layer and mode ratio of propagation mode, in an organic electroluminescence element that emits green light;

FIG. 9 depicts an example of the relation between refractive index of a low refractive index layer and mode ratio of propagation mode, in an organic electroluminescence element that emits blue light;

FIG. 10 is a figure depicting a modification of the sectional configuration of the organic electroluminescence element of FIG. 1;

FIG. 11 is a figure depicting a modification of the sectional configuration of the organic electroluminescence element of FIG. 1;

FIG. 12 is a figure depicting a modification of the sectional configuration of the organic electroluminescence element of FIG. 10;

FIG. 13 is a figure depicting an example of the sectional configuration of the organic electroluminescence elements of FIGS. 11 and 12;

FIG. 14 is a figure depicting an example of the sectional configuration of the organic electroluminescence elements of FIGS. 11 and 12;

FIG. 15 is a figure depicting an example of the sectional configuration of the organic electroluminescence elements of FIGS. 11 and 12;

FIG. 16 is a figure depicting a general configuration example of an organic electroluminescence device according to a second embodiment of the present disclosure;

FIG. 17 is a figure depicting a circuit configuration example of a sub-pixel included in each pixel of FIG. 16;

FIG. 18 is a figure depicting a general configuration example of an organic electroluminescence panel of FIG. 16;

FIG. 19 is a figure depicting a sectional configuration example, along line A-A, of the organic electroluminescence panel of FIG. 18;

FIG. 20 is a figure depicting a sectional configuration example, along line B-B, of the organic electroluminescence panel of FIG. 18;

FIG. 21 is a figure depicting a sectional configuration example, along line C-C, of the organic electroluminescence panel of FIG. 18;

FIG. 22 is a figure depicting a modification of the general configuration of the organic electroluminescence panel of FIG. 16;

FIG. 23 is a figure depicting a sectional configuration example, along line B-B, of the organic electroluminescence panel of FIG. 22;

FIG. 24 is a figure depicting a sectional configuration example, along line C-C, of the organic electroluminescence panel of FIG. 22;

FIG. 25 is a figure depicting a modification of the sectional configuration, along line A-A, of the organic electroluminescence panel of FIG. 18;

FIG. 26 is a figure depicting a modification of the sectional configuration, along line B-B, of the organic electroluminescence panel of FIG. 18;

FIG. 27 is a figure depicting a modification of the sectional configuration, along line C-C, of the organic electroluminescence panel of FIG. 18;

FIG. 28 is a figure depicting on an oblique view basis an example of external appearance of an electronic apparatus including an organic electroluminescence device of the present disclosure; and

FIG. 29 is a figure depicting on an oblique view basis an example of external appearance of an illumination device including an organic electroluminescence element of the present disclosure.

### DETAILED DESCRIPTION OF THE PREFERRED EMBODIMENTS

Embodiments of the present disclosure will be described in detail below, referring to the drawings. The embodiments described below are preferable specific examples of the present disclosure. Therefore, the numerical values, shapes, materials, components, layout positions and connection forms of the components, and the like indicated in the following embodiments are mere examples and are not limitative of the present disclosure. Accordingly, those of the components in the following embodiments which are not described in the independent claims describing the broadest concept of the present disclosure are described as arbitrary components. Note that the drawings are schematic figures, which are not necessarily drawn strictly. In addition, in the drawings, substantially the same configurations are denoted by the same reference signs, and repeated descriptions thereof will be omitted or simplified. Note that the descriptions will be made in the following order.

1. First Embodiment (Organic Electroluminescence Element)

Example in which low refractive index layer is provided between light emitting layer and cathode

2. Modifications of First Embodiment (Organic Electroluminescence Element)

Modification A: Example in which low refractive index layer is provided between anode and light emitting layer

Modification B: Example in which hole injection layer is configured as stacked body

Modification C: Example in which light distribution control layer is provided over cathode

3. Second Embodiment (Organic Electroluminescence Panel and Organic Electroluminescence Device)

Examples in which organic electroluminescence elements according to first embodiment, modification A and modification B are respectively provided

4. Modification of Second Embodiment (Organic Electroluminescence Panel and Organic Electroluminescence Device)

Example in which organic electroluminescence element according to modification C is provided

5. Application Examples (Electronic Apparatus and Illumination Device)

### 1. FIRST EMBODIMENT

### [Configuration]

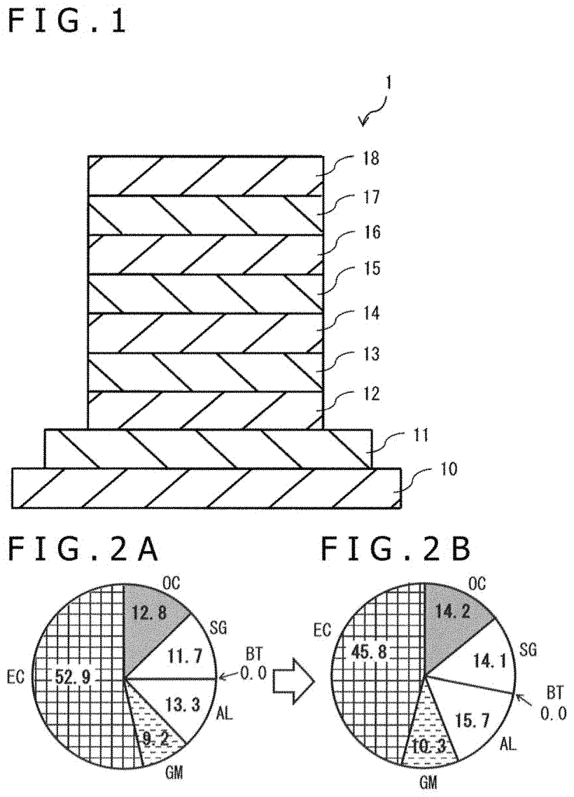

FIG. 1 depicts an example of a sectional configuration of an organic electroluminescence element 1 according to a first embodiment of the present disclosure. The organic electroluminescence element 1 is provided, for example, over a substrate 10. The organic electroluminescence element 1 includes, for example, a light emitting layer 14, and an anode 11 and a cathode 17 which are disposed such as to sandwich the light emitting layer 14 therebetween. The organic electroluminescence element 1 further includes, for example, a hole injection layer 12 and a hole transport layer 13, between the anode 11 and the light emitting layer 14, in this order from the anode 11 side. The organic electroluminescence element 1 further includes, for example, an electron transport layer 15 and an electron injection layer 16, between the light emitting layer 14 and the cathode 17, in this order from the light emitting layer 14 side. Note that at least one of the hole injection layer 12 and the hole transport layer 13 may be omitted.

Either one of the electron transport layer 15 and the electron injection layer 16 corresponds to a specific example of a “low refractive index layer” in the present disclosure. Hereinafter, that one of the electron transport layer 15 and the electron injection layer 16 which corresponds to the specific example of the “low refractive index layer” in the present disclosure will be referred to as the low refractive index layer. Note that that layer of the electron transport layer 15 and the electron injection layer 16 which does not correspond to the specific example of the “low refractive index layer” in the present disclosure may be omitted.

The organic electroluminescence element 1 further includes, for example, a sealing layer 18 over the cathode 17. The organic electroluminescence element 1 has an element structure configured to include, for example, the anode 11, the hole injection layer 12, the hole transport layer 13, the light emitting layer 14, the electron transport layer 15, the electron injection layer 16, the cathode 17 and the sealing layer 18 in this order from the substrate 10 side. The organic electroluminescence element 1 may further include other functional layers.

The substrate 10 is, for example, a light-transmitting substrate having a light-transmitting property such as a transparent substrate, and is, for example, a glass substrate formed of a glass material. Note that the substrate 10 is not limited to the glass substrate, but may be a light-transmitting resin substrate formed of a light-transmitting resin material such as a polycarbonate resin or an acrylic resin, or may be a thin film transistor (TFT) substrate which is a backplane of an organic EL display device.

The anode 11 is formed, for example, over the substrate 10. The anode 11 is, for example, aluminum (Al), silver (Ag), or an aluminum or silver alloy or the like, or a reflective electrode having a reflecting property. Note that the anode 11 is not limited to a reflective electrode, but may be, for example, a light-transmitting transparent electrode. Examples of the material for the transparent electrode include transparent conductive materials such as indium tin oxide (ITO) or indium zinc oxide (IZO). The anode 11 may be a stacked body of a reflective electrode and a transparent electrode.

The hole injection layer 12 is a layer for enhancing hole injection efficiency. The hole injection layer 12 has a function of injecting holes, injected from the anode 11, into the light emitting layer 14. The hole injection layer 12 is configured using, for example, an oxide of silver (Ag), molybdenum (Mo), chromium (Cr), vanadium (V), tungsten (W), nickel (Ni), iridium (Ir) or the like, or a conductive polymer material such as PEDOT (a mixture of polythiophene and polystyrenesulfonic acid). The hole injection layer 12 may be composed of a single layer, or may have a stacked structure of a plurality of layers.

The hole transport layer 13 has a function of transporting holes, injected from the anode 11, to the light emitting layer 14. The hole transport layer 13 is configured using, for example, a material (hole transporting material) that has a function of transporting the holes, injected from the anode 11, to the light emitting layer 14. Examples of the hole transporting material include arylamine derivatives, triazole derivatives, oxadiazole derivatives, imidazole derivatives, polyaryalalkane derivatives, pyrazoline derivatives and pyrazolone derivatives, phenylenediamine derivatives, amino-substituted chalcone derivatives, oxazole derivatives, styrylanthracene derivatives, fluorenone derivatives, hydrozone derivatives, stilbene derivatives, butadiene derivatives, polystyrene derivatives, triphenylmethane derivatives, tetraphenylbenzine derivatives, and their combinations. The difference in highest occupied molecular orbital (HOMO) level between the materials of the hole injection layer 12 and the hole transport layer 13 is preferably not more than 0.5 eV, taking into account a hole injecting property.

The light emitting layer 14 is a layer in which holes injected from the anode 11 and electrons injected from the cathode 17 are re-combined with each other to produce excitons, thereby emitting light. The light emitting layer 14 is configured using, for example, an organic light emitting material. The light emitting layer 14 is, for example, a coating film, and is formed, for example, by applying a solution containing the organic light emitting material as solute, followed by drying. The light emitting layer 14 may be configured using a vapor deposited film.

The organic light emitting material as the raw material (material) for the light emitting layer 14 is, for example, a material obtained by combining a host material and a dopant material. The organic light emitting material as the raw material (material) for the light emitting layer 14 may be a dopant material alone. The host material is mainly in charge of the function of transporting carriers such as electrons or holes, while the dopant material is in charge of the function of emitting light. The host material and the dopant material are each not limited to one kind of material, and may each be a combination of two or more kinds of materials.

As the host material of the light emitting layer 14, there is used, for example, an amine compound, a condensed polycyclic aromatic compound, or a heterocyclic compound. As the amine compound, there may be used, for example, monoamine derivatives, diamine derivatives, triamine derivatives, and tetraamine derivatives. Examples of the condensed polycyclic aromatic compound include anthracene derivatives, naphthalene derivatives, naphthacene derivatives, phenanthrene derivatives, chrysene derivatives, fluoranthene derivatives, triphenylene derivatives, pentacene derivatives, and perylene derivatives. Examples of the heterocyclic compound include carbazole derivatives, furan derivatives, pyridine derivatives, pyrimidine derivatives, triazine derivatives, imidazole derivatives, pyrazole derivatives, triazole derivatives, oxazole derivatives, oxadiazole derivatives, pyrrole derivatives, indole derivatives, azaindole derivatives, azacarbazole derivatives, pyrazoline derivatives, pyrazolone derivatives, and phthalocyanine derivatives.

In addition, as the dopant material of the light emitting layer 14, there is used, for example, a pyrene derivative, a fluoranthene derivative, an arylacetylene derivative, a fluorene derivative, a perylene derivative, an oxadiazole derivative, an anthracene derivative, or a chrysene derivative. Besides, as a fluorescent dopant material of the light emitting layer 14, a metal complex may be used. Examples of the metal complex include those having a metal atom of iridium (Ir), platinum (Pt), Osmium (Os), gold (Au), rhenium (Re), ruthenium (Ru) or the like and a ligand.

The electron transport layer 15 has a function of transporting electrons, injected from the cathode 17, to the light emitting layer 14. The electron transport layer 15 includes, for example, a material (electron transporting material) having a function of transporting the electrons, injected from the cathode 17, to the light emitting layer 14. The electron transport layer 15 is configured using, for example, a vapor deposited film or a sputtered film. The electron transport layer 15 preferably has a charge blocking function of restraining charges (in the present embodiment, holes) from penetrating from the light emitting layer 14 to the cathode 17, a function of restraining quenching of an excited state of the light emitting layer 14, or the like.

The above-mentioned electron transporting material is, for example, an aromatic heterocyclic compound having at least one hetero-atom in its molecule. Examples of the aromatic heterocyclic compound include those compounds which include a pyridine ring, a pyrimidine ring, a triazine ring, a benzimidazole ring, a phenanthroline ring, a quinazoline ring or the like in the skeleton thereof. The electron transporting material may be doped with a metal having an electron transporting property. In this case, the electron transport layer 15 is an organic electron transport layer containing a dopant metal. Where the metal having an electron transporting property is contained in the electron transport layer 15, electron transporting property of the electron transport layer 15 can be enhanced thereby. Examples of the dopant metal contained in the electron transport layer 15 include transition metals such as ytterbium (Yb).

The electron injection layer 16 has a function of injecting electrons, injected from the cathode 17, to the electron transport layer 15 and the light emitting layer 14. The electron injection layer 16 is configured using, for example, a material (electron injecting material) having a function of accelerating the injection of electrons from the cathode 17 to the electron transport layer 15 and the light emitting layer 14. The electron injecting material may be, for example, a material obtained by doping an organic material having an electron injecting property with a metal having an electron injecting property. The dopant metal contained in the electron injection layer 16 is, for example, the same metal as the dopant metal contained in the electron transport layer 15.

The cathode 17 is, for example, a transparent electrode such as an ITO film. Note that the cathode 17 is not limited to the transparent electrode, but may be a reflective electrode having a light-reflecting property. As the material for the reflective electrode, there is used, for example, aluminum (Al), magnesium (Mg), silver (Ag), an aluminum-lithium alloy, or a magnesium-silver alloy. In the present embodiment, in the case where the substrate 10 and the anode 11 are reflective and the cathode 17 is light-transmitting, the organic electroluminescence element 1 is of a top emission structure in which light is released from the cathode 17 side. Note that in the present embodiment, in the case where the substrate 10 and the anode 11 are light-transmitting and the cathode 17 is reflective, the organic electroluminescence element 1 is of a bottom emission structure in which light is released from the substrate 10 side.

The sealing layer 18 is formed over the cathode 17. The sealing layer 18 is formed, for example, in contact with an upper surface of the cathode 17. The sealing layer 18 is formed, for example, of a resin material. Examples of the resin material to be used for the sealing layer 18 include epoxy resins and vinyl resins.

The low refractive index layer will be described below. The low refractive index layer is provided between the light emitting layer 14 and the cathode 17, and is either one of the electron transport layer 15 and the electron injection layer 16. In other words, the low refractive index layer has a function of injecting or transporting electrons, injected from the cathode 17, into the light emitting layer 14. Note that in the case where the electron injection layer 16 is configured using a single layer, the low refractive index layer may, for example, correspond to the whole part of the electron injection layer 16. In the case where the electron injection layer 16 is configured using a stacked body of a plurality of layers, the low refractive index layer may, for example, correspond to the whole part of the electron injection layer 16 or may correspond to at least one layer included in the electron injection layer 16. In addition, in the case where the electron transport layer 15 is configured using a single layer, the low refractive index layer may, for example, correspond to the whole part of the electron transport layer 15. In the case where the electron transport layer 15 is configured using a stacked body of a plurality of layers, the low refractive index layer may, for example, correspond to the whole part of the electron transport layer 15 or may correspond to at least one layer included in the electron transport layer 15.

The low refractive index layer is formed using a material that has a refractive index different from those of the light emitting layer 14 and the cathode 17. Specifically, the low refractive index layer has a refractive index higher than the refractive index of the cathode 17 and lower than the refractive index of the light emitting layer 14. Here, in the case where the cathode 17 is configured using, for example, a metallic material having a refractive index of 0.3 and the light emitting layer 14 is configured using, for example, an organic material having a refractive index of 1.7, the low refractive index layer is configured using a material having a refractive index higher than 0.3 and lower than 1.7.

FIG. 2A depicts an example of mode ratio of propagation mode of energy generated in an organic electroluminescence element according to a comparative example. FIG. 2B depicts a configuration example of propagation mode of energy generated in an organic electroluminescence element according to a working example. In the working example, the refractive index of either one of the electron transport layer 15 and the electron injection layer 16 is higher than the refractive index of the cathode 17 and lower than the refractive index of the light emitting layer 14. The other conditions in the comparative example and the working example are as follows. Note that in FIGS. 2A and 2B, OC indicates an external release mode, SG indicates a substrate mode, BT indicates a mode (leakage mode) of leakage to the side opposite to the sealing layer 18 (namely, to the substrate 10 side), AL indicates a mode (loss mode) of generation of loss due to absorption in the organic electroluminescence element, GM indicates a waveguide mode, and EC indicates an evanescent mode.

In FIGS. 2A and 2B are indicated simulation results for an organic electroluminescence element having a microcavity structure in which secondary interference (second cavity) is generated and the light emission position is on the cathode side. Here, in the comparative example, the anode was configured using a material having a thickness of 200 nm and a refractive index of 0.7, the hole injection layer was configured using a material having a thickness of 10 nm and a refractive index of 1.7, the hole transport layer was configured using a material having a thickness of 180 nm and a refractive index of 1.7, and the light emitting layer 14 was configured using a material having a thickness of 60 nm and a refractive index of 1.7.

In the comparative example, further, the electron transport layer was configured using a material having a thickness of 10 nm and a refractive index of 1.8, the electron injection layer was configured using a material having a thickness of 10 nm and a refractive index of 2.0, the cathode was configured using a material having a thickness of 15 nm and a refractive index of 0.3, and the sealing layer was configured using a material having a thickness of 5 μm and a refractive index of 1.8. On the other hand, in the working example, the anode 11 was configured using a material having a thickness of 200 nm and a refractive index of 0.7, the hole injection layer 12 was configured using a material having a thickness of 10 nm and a refractive index of 1.7, the hole transport layer 13 was configured using a material having a thickness of 180 nm and a refractive index of 1.7, and the light emitting layer 14 was configured using a material having a thickness of 60 nm and a refractive index of 1.7. In the working example, further, the electron transport layer 15 was configured using a material having a thickness of 10 nm and a refractive index of 1.8, the electron injection layer 16 was configured using a material having a thickness of 10 nm and a refractive index of 1.3, the cathode 17 was configured using a material having a thickness of 15 nm and a refractive index of 0.3, and the sealing layer 18 was configured using a material having a thickness of 5 μm and a refractive index of 1.8.

From FIGS. 2A and 2B, it is seen that provision of the low refractive index layer between the light emitting layer 14 and the cathode 17 causes transition of photon energy from an evanescent mode to a waveguide mode. In addition, it is also seen that the transition of photon energy from the evanescent mode to the waveguide mode is attended by an increase in the external release mode. Note that the photon energy having transited to the waveguide mode is reflected, for example, by a reflector structure described in a second embodiment, and can be emitted to the exterior as light build up toward the front direction.

Meanwhile, the provision of the low refractive index layer between the light emitting layer 14 and the cathode 17 means, to the light going from the light emitting layer 14 toward the low refractive index layer, that the critical angle at the interface of the low refractive index layer is decreased. Therefore, in the present embodiment and the working example, the proportion in which the light going from the light emitting layer 14 toward the low refractive index layer is reflected at the interface of the low refractive index layer is enhanced, as compared to the case where the low refractive index layer is not provided. As a result, the proportion of evanescent deactivation due, for example, to surface plasmon in the vicinity of the anode 11 is lowered, so that the external release mode and the waveguide mode are increased. In addition, there has been a report that the energy radiation distribution from excitons varies largely under the influences of the properties (dielectric constant, refractive index, etc.) of the ambient environment (materials) and that, for example, if a field of a high refractive index is present, energy is radiated toward the field. It is assumed that the proportions of transition to other modes are increased, also through such a phenomenon.

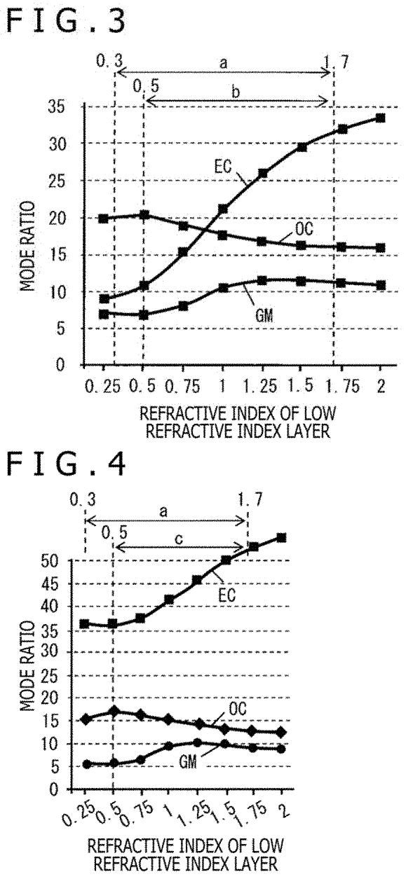

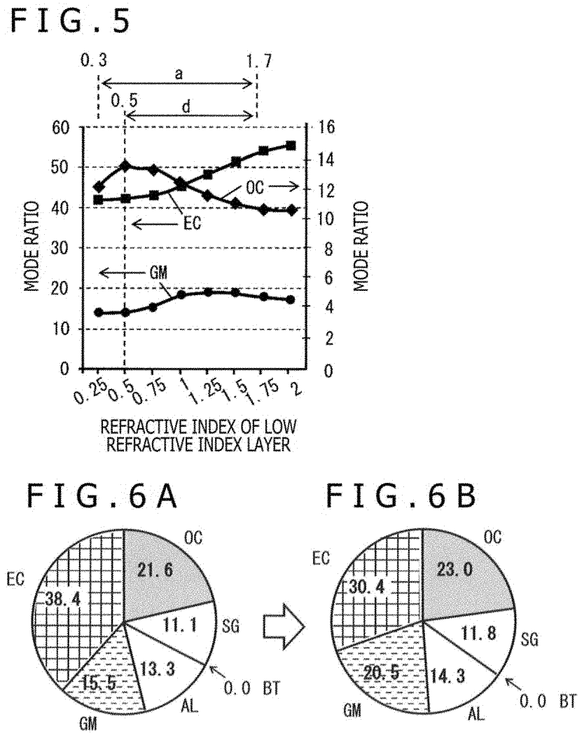

FIG. 3 depicts an example of the relation between the refractive index of the low refractive index layer and mode ratios of propagation modes, for an organic electroluminescence element 1 that emits red light. FIG. 4 depicts an example of the relation between the refractive index of the low refractive index layer and mode ratios of propagation modes, for an organic electroluminescence element 1 that emits green light. FIG. 5 depicts an example of the relation between the refractive index of the low refractive index layer and mode ratios of propagation modes, for an organic electroluminescence element 1 that emits blue light.

FIGS. 3 to 5 exemplify simulation results concerning the case where the organic electroluminescence element 1 has a microcavity structure in which secondary interference (second cavity) is generated and the light emission position is on the cathode 17 side. The refractive index of the low refractive index layer on the axis of abscissas depicted in FIGS. 3 to 5 indicates the refractive index of the electron injection layer 16.

In FIG. 3, the anode 11 was configured using a material having a thickness of 200 nm and a refractive index of 0.3, the hole injection layer 12 was configured using a low refractive index material in a thickness of 10 nm, the hole transport layer 13 was configured using a material having a thickness of 220 nm and a refractive index of 1.7, and the light emitting layer 14 was configured using a material having a thickness of 60 nm and a refractive index of 1.7. In addition, in FIG. 3, the electron transport layer 15 was configured using a material having a thickness of 10 nm and a refractive index of 1.8, the electron injection layer 16 was configured in a thickness of 10 nm, the cathode 17 was configured using a material having a thickness of 15 nm and a refractive index of 0.3, and the sealing layer 18 was configured using a material having a thickness of 5 μm and a refractive index of 1.8.

In FIG. 4, the anode 11 was configured using a material having a thickness of 200 nm and a refractive index of 0.3, the hole injection layer 12 was configured using a low refractive index material in a thickness of 10 nm, the hole transport layer 13 was configured using a material having a thickness of 180 nm and a refractive index of 1.7, and the light emitting layer 14 was configured using a material having a thickness of 60 nm and a refractive index of 1.7. In addition, in FIG. 4, the electron transport layer 15 was configured using a material having a thickness of 10 nm and a refractive index of 1.8, the electron injection layer 16 was configured in a thickness of 10 nm, the cathode 17 was configured using a material having a thickness of 15 nm and a refractive index of 0.3, and the sealing layer 18 was configured using a material having a thickness of 5 μm and a refractive index of 1.8.

In FIG. 5, the anode 11 was configured using a material having a thickness of 200 nm and a refractive index of 0.3, the hole injection layer 12 was configured using a low refractive index material in a thickness of 10 nm, the hole transport layer 13 was configured using a material having a thickness of 140 nm and a refractive index of 1.7, and the light emitting layer 14 was configured using a material having a thickness of 40 nm and a refractive index of 1.7. Besides, in FIG. 5, the electron transport layer 15 was configured using a material having a thickness of 10 nm and a refractive index of 1.8, the electron injection layer 16 was configured in a thickness of 10 nm, the cathode 17 was configured using a material having a thickness of 15 nm and a refractive index of 0.3, and the sealing layer 18 was configured using a material having a thickness of 5 μm and a refractive index of 1.8.

As aforementioned, in the organic electroluminescence elements 1 that emit light in respective colors, the refractive index of the low refractive index layer is preferably higher than the refractive index (for example, 0.3) of the cathode 17 and lower than the refractive index (for example, 1.7) of the light emitting layer 14. In the organic electroluminescence element 1 that emits red light, the refractive index of the low refractive index layer is preferably not less than 0.5, at which the proportion of the waveguide mode increases. Therefore, in the organic electroluminescence element 1 that emits red light, the refractive index of the low refractive index layer is preferably a value in the range “a” in FIG. 3, more preferably a value in the range “b” in FIG. 3.

In the organic electroluminescence element 1 that emits green light, the refractive index of the low refractive index layer is preferably not less than 0.5, at which the proportion of the waveguide mode increases. Therefore, in the organic electroluminescence element 1 that emits green light, the refractive index of the low refractive index layer is preferably a value in the range “a” in FIG. 4, more preferably a value in the range “c” in FIG. 4.

In the organic electroluminescence element 1 that emits blue light, the refractive index of the low refractive index layer is preferably not less than 0.5, at which the proportion of the waveguide mode increases. Therefore, in the organic electroluminescence element 1 that emits blue light, the refractive index of the low refractive index layer is preferably a value in the range “a” in FIG. 5, more preferably a value in the range “d” in FIG. 5.

### [Effect]

Effects of the organic electroluminescence element 1 according to the present embodiment will be described below.

As an organic electroluminescence device using an organic electroluminescence element, a variety of ones have been proposed. The organic electroluminescence element is an element in which electrons and holes injected from a cathode and an anode re-combine with each other in a light emitting layer, to generate excitons, and the excitons release light when returning to a lower energy level or a ground state. Therefore, in the organic electroluminescence element, it is necessary to effectively inject the carriers and to effectively extract the light to the exterior.

Here, paying attention to hole injection, of carrier injection, it is important that the hole injection layer 12 injects holes into the light emitting layer 14 and has a function of lowering the proportion of generation of deactivation in which the energy of the excitons produced at the light emission center is lost in the vicinity of the anode 11. In view of this, in the present embodiment, the low refractive index layer having a refractive index higher than the refractive index of the cathode 17 and lower than the refractive index of the light emitting layer 14 is provided between the light emitting layer 14 and the cathode 17. This ensures that to the light going from the light emitting layer 14 toward the low refractive index layer, the critical angle at the interface of the low refractive index layer is reduced, and, therefore, the proportion in which the light going from the light emitting layer 14 toward the low refractive index layer is reflected at the interface of the low refractive index layer is enlarged, as compared to the case where the low refractive index layer is not provided. As a result, the proportion of evanescent deactivation of excitons due, for example, to surface plasmon in the vicinity of the anode 11 is lowered, and, therefore, the proportions of the external release mode and the waveguide mode are increased. Accordingly, the injection or transport of holes into the light emitting layer 14 can be promoted and light extraction efficiency can be enhanced, by the low refractive index layer.

In addition, in the present embodiment, in the case where the low refractive index layer is configured using a material having a refractive index of higher than 0.3 and lower than 1.7, to the light going from the light emitting layer 14 toward the low refractive index layer, the critical angle at the interface of the low refractive index layer is reduced, and, therefore, the proportion in which the light going from the light emitting layer 14 toward the low refractive index layer is reflected at the interface of the low refractive index layer is enlarged, as compared to the case where the low refractive index layer is not provided. As a result, the proportion of evanescent deactivation of excitons due, for example, to surface plasmon in the vicinity of the anode 11 is reduced, and, therefore, the proportions of the external release mode and the waveguide mode are increased. Accordingly, the injection or transport of holes into the light emitting layer 14 can be promoted and light extraction efficiency can be enhanced, by the low refractive index layer.

In addition, in the organic electroluminescence element 1 that emits red light according to the present embodiment, in the case where the refractive index of the low refractive index layer is 0.5 to 1.7, the proportion of the waveguide mode is enhanced. This ensures that the injection or transport of holes into the light emitting layer 14 can be promoted and light extraction efficiency can be enhanced.

Besides, in the organic electroluminescence element 1 that emits green light according to the present embodiment, in the case where the refractive index of the low refractive index layer is 0.5 to 1.7, the proportion of the waveguide mode is enhanced. This ensures that the injection or transport of holes into the light emitting layer 14 can be promoted and light extraction efficiency can be enhanced.

In addition, in the organic electroluminescence element 1 that emits blue light according to the present embodiment, in the case where the refractive index of the low refractive index layer is 0.5 to 1.7, the proportion of the waveguide mode is enhanced. This ensures that the injection or transport of holes into the light emitting layer 14 can be promoted and light extraction efficiency can be enhanced.

### 2. MODIFICATIONS OF FIRST EMBODIMENT

A modification of the organic electroluminescence element 1 according to the first embodiment will be described below.

### [Modification A]

In the above embodiment, the low refractive index layer has been provided between the light emitting layer 14 and the cathode 17. However, in the above embodiment, the low refractive index layer may be provided not between the light emitting layer 14 and the cathode 17 but between the anode 11 and the light emitting layer 14. In addition, in the above embodiment, the low refractive index layer may be provided between the light emitting layer 14 and the cathode 17 and is also provided between the anode 11 and the light emitting layer 14. Hereinafter, the low refractive index layer provided between the anode 11 and the light emitting layer 14 will be described.

The low refractive index layer is provided between the anode 11 and the light emitting layer 14, and is either one of the hole injection layer 12 and the hole transport layer 13. In other words, the low refractive index layer has a function of injecting or transporting holes, injected from the anode 11, into the light emitting layer 14. Note that in the case where the hole injection layer 12 is configured using a single layer, the low refractive index layer may correspond, for example, to the whole part of the hole injection layer 12. In the case where the hole injection layer 12 is configured using a stacked body of a plurality of layers, the low refractive index layer may correspond, for example, to the whole part of the hole injection layer 12 or may correspond to at least one layer included in the hole injection layer 12. In addition, in the case where the hole transport layer 13 is configured using a single layer, the low refractive index layer may correspond, for example, to the whole part of the hole transport layer 13. In the case where the hole transport layer 13 is configured using a stacked body of a plurality of layers, the low refractive index layer may correspond, for example, to the whole part of the hole transport layer 13 or may correspond to at least one layer included in the hole transport layer 13.

The low refractive index layer is formed using a material having a refractive index different from those of the anode 11 and the light emitting layer 14. Specifically, the low refractive index layer has a refractive index higher than the refractive index of the anode 11 and lower than the refractive index of the light emitting layer 14. Here, in the case where the anode 11 is configured using, for example, a metallic material having a refractive index of 0.3 and the light emitting layer 14 is configured using, for example, an organic material having a refractive index of 1.7, the low refractive index layer is configured using a material having a refractive index higher than 0.3 and lower than 1.7.

FIG. 6A depicts an example of mode ratios of propagation modes of energy generated in an organic electroluminescence element according to a comparative example. FIG. 6B depicts a configuration example of mode ratios of propagation modes of energy generated in an organic electroluminescence element according to a working example. In the comparative example, the refractive indexes of the hole injection layer 12 and the hole transport layer 13 are both equal to the refractive index of the light emitting layer 14. On the other hand, in the working example, the refractive index of either one of the hole injection layer 12 and the hole transport layer 13 is higher than the refractive index of the anode 11 and lower than the refractive index of the light emitting layer 14. The other conditions in the comparative example and the working example are as follows. Note that in FIGS. 6A and 6B, OC indicates an external release mode, SG indicates a substrate mode, BT indicates a mode (leakage mode) of leakage to the side opposite to the sealing layer 18 (namely, to the substrate 10 side), AL indicates a mode (loss mode) of generation of loss due to absorption in the organic electroluminescence element, GM indicates a waveguide mode, and EC indicates an evanescent mode.

In FIGS. 6A and 6B are indicated simulation results for an organic electroluminescence element having a microcavity structure in which secondary interference (second cavity) is generated and the light emission position is on the anode side. Here, in the comparative example, the anode was configured using a material having a thickness of 200 nm and a refractive index of 0.7, the hole injection layer was configured using a material having a thickness of 10 nm and a refractive index of 1.7, the hole transport layer was configured using a material having a thickness of 20 nm and a refractive index of 1.7, and the light emitting layer 14 was configured using a material having a thickness of 90 nm and a refractive index of 1.7.

In the comparative example, further, the electron transport layer was configured using a material having a thickness of 30 nm and a refractive index of 1.8, the electron injection layer was configured using a material having a thickness of 80 nm and a refractive index of 2.0, the cathode was configured using a material having a thickness of 15 nm and a refractive index of 0.3, and the sealing layer was configured using a material having a thickness of 5 μm and a refractive index of 1.8. On the other hand, in the working example, the anode 11 was configured using a material having a thickness of 200 nm and a refractive index of 0.7, the hole injection layer 12 was configured using a material having a thickness of 10 nm and a refractive index of 1.3, the hole transport layer 13 was configured using a material having a thickness of 20 nm and a refractive index of 1.7, and the light emitting layer 14 was configured using a material having a thickness of 90 nm and a refractive index of 1.7. In the working example, further, the electron transport layer 15 was configured using a material having a thickness of 30 nm and a refractive index of 1.8, the electron injection layer 16 was configured using a material having a thickness of 80 nm and a refractive index of 2.0, the cathode 17 was configured using a material having a thickness of 15 nm and a refractive index of 0.3, and the sealing layer 18 was configured using a material having a thickness of 5 μm and a refractive index of 1.8.

From FIGS. 6A and 6B, it is seen that the provision of the low refractive index layer between the anode 11 and the light emitting layer 14 causes transition of photon energy from the evanescent mode to the waveguide mode. In addition, it is also seen that the transition of the photon energy from the evanescent mode to the waveguide mode is attended by an increase in the external release mode. Note that the photon energy having transited to the waveguide mode is reflected, for example, by a reflector structure to be described in the second embodiment, and can be emitted to the exterior as light built up toward the front direction.

Meanwhile, the provision of the low refractive index layer between the anode 11 and the light emitting layer 14 means, to the light going from the light emitting layer 14 toward the low refractive index layer, that the critical angle at the interface of the low refractive index layer is decreased. Therefore, in the present embodiment and the working example, the proportion in which the light going from the light emitting layer 14 toward the low refractive index layer is reflected at the interface of the low refractive index layer is enhanced, as compared to the case where the low refractive index layer is not provided. As a result, the proportion of evanescent deactivation due, for example, to surface plasmon in the vicinity of the anode 11 is lowered, so that the external release mode and the waveguide mode are increased. In addition, there has been a report that the energy radiation distribution from excitons varies largely under the influences of the properties (dielectric constant, refractive index, etc.) of the ambient environment (materials) and that, for example, if a field of a high refractive index is present, energy is radiated toward the field. It is assumed that the proportions of transition to other modes are increased, also through such a phenomenon.

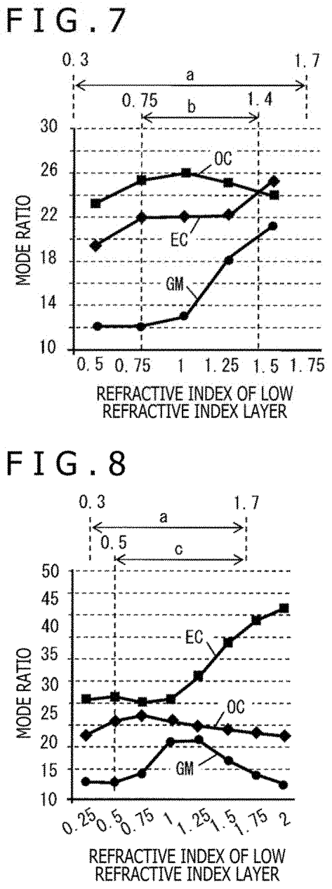

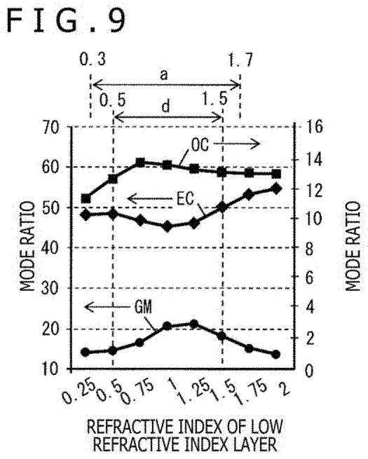

FIG. 7 depicts an example of the relation between the refractive index of the low refractive index layer and mode ratios of propagation modes, in an organic electroluminescence element 1 that emits red light. FIG. 8 depicts an example of the relation between the refractive index of the low refractive index layer and mode ratios of propagation modes, in an organic electroluminescence element 1 that emits green light. FIG. 9 depicts an example of the relation between the refractive index of the low refractive index layer and mode ratios of propagation modes, in an organic electroluminescence element 1 that emits blue light.

In FIGS. 7 to 9 are indicated simulation results in the case where the organic electroluminescence element 1 has a microcavity structure in which secondary interference (second cavity) is generated and the light emission position is on the anode 11 side. The refractive index of the low refractive index layer on the axis of abscissas depicted in FIGS. 7 to 9 indicates the refractive index of the hole injection layer 12.

In FIG. 6, the anode 11 was configured using a material having a thickness of 200 nm and a refractive index of 0.3, the hole injection layer 12 was configured using a low refractive index material in a thickness of 10 nm, the hole transport layer 13 was configured using a material having a thickness of 30 nm and a refractive index of 1.7, and the light emitting layer 14 was configured using a material having a thickness of 120 nm and a refractive index of 1.7. In addition, in FIG. 6, the electron transport layer 15 was configured using a material having a thickness of 30 nm and a refractive index of 1.8, the electron injection layer 16 was configured using a material having a thickness of 80 nm and a refractive index of 2.0, the cathode 17 was configured using a material having a thickness of 15 nm and a refractive index of 0.3, and the sealing layer 18 was configured using a material having a thickness of 5 μm and a refractive index of 1.8.

In FIG. 7, the anode 11 was configured using a material having a thickness of 200 nm and a refractive index of 0.3, the hole injection layer 12 was configured using a low refractive index material in a thickness of 10 nm, the hole transport layer 13 was configured using a material having a thickness of 20 nm and a refractive index of 1.7, and the light emitting layer 14 was configured using a material having a thickness of 90 nm and a refractive index of 1.7. In addition, in FIG. 7, the electron transport layer 15 was configured using a material having a thickness of 30 nm and a refractive index of 1.8, the electron injection layer 16 was configured using a material having a thickness of 80 nm and a refractive index of 2.0, the cathode 17 was configured using a material having a thickness of 15 nm and a refractive index of 0.3, and the sealing layer 18 was configured using a material having a thickness of 5 μm and a refractive index of 1.8.

In FIG. 8, the anode 11 was configured using a material having a thickness of 200 nm and a refractive index of 0.3, the hole injection layer 12 was configured using a low refractive index material in a thickness of 10 nm, the hole transport layer 13 was configured using a material having a thickness of 20 nm and a refractive index of 1.7, and the light emitting layer 14 was configured using a material having a thickness of 40 nm and a refractive index of 1.7. Besides, in FIG. 8, the electron transport layer 15 was configured using a material having a thickness of 30 nm and a refractive index of 1.8, the electron injection layer 16 was configured using a material having a thickness of 80 nm and a refractive index of 2.0, the cathode 17 was configured using a material having a thickness of 15 nm and a refractive index of 0.3, and the sealing layer 18 was configured using a material having a thickness of 5 μm and a refractive index of 1.8.

As aforementioned, in the organic electroluminescence elements 1 that emit light in respective colors, the refractive index of the low refractive index layer is preferably higher than the refractive index (for example, 0.3) of the anode 11 and lower than the refractive index (for example, 1.7) of the light emitting layer 14. In the organic electroluminescence element 1 that emits red light, the refractive index of the low refractive index layer is preferably not less than 0.75, at which the proportion of the waveguide mode increases. In the organic electroluminescence element 1 that emits red light, the refractive index of the low refractive index layer is preferably not more than 1.4, at which the external release mode becomes predominant over the evanescent mode. Therefore, in the organic electroluminescence element 1 that emits red light, the refractive index of the low refractive index layer is preferably a value in the range “a” in FIG. 7, more preferably a value in the range “b” in FIG. 7.

In the organic electroluminescence element 1 that emits green light, the refractive index of the low refractive index layer is preferably not less than 0.5, at which the proportion of the waveguide mode increases. Therefore, in the organic electroluminescence element 1 that emits green light, the refractive index of the low refractive index layer is preferably a value in the range “a” in FIG. 8, more preferably a value in the range “c” in FIG. 8.

In the organic electroluminescence element 1 that emits blue light, the refractive index of the low refractive index layer is preferably not less than 0.5, at which the proportion of the waveguide mode increases. In the organic electroluminescence element 1 that emits blue light, the refractive index of the low refractive index layer is preferably not more than 1.5, at which the proportion of the evanescent mode becomes not more than 50%. Therefore, in the organic electroluminescence element 1 that emits blue light, the refractive index of the low refractive index layer is preferably a value in the range “a” in FIG. 9, more preferably a value in the range “d” in FIG. 9.

### [Effect]

Effects of the organic electroluminescence element 1 according to the present modification will be described below.

In the present modification, the low refractive index layer having a refractive index higher than the refractive index of the anode 11 and lower than the refractive index of the light emitting layer 14 is provided between the anode 11 and the light emitting layer 14. This ensures that, to the light going from the light emitting layer 14 toward the low refractive index layer, the critical angle at the interface of the low refractive index layer is reduced, and, therefore, the proportion in which the light going from the light emitting layer 14 toward the low refractive index layer is reflected at the interface of the low refractive index layer is enhanced, as compared to the case where the low refractive index layer is not provided. As a result, the proportion of evanescent deactivation of excitons due, for example, to surface plasmon in the vicinity of the anode 11 is lowered, and, therefore, the proportions of the external release mode and the waveguide mode are increased. Accordingly, the injection or transport of holes into the light emitting layer 14 can be promoted and light extraction efficiency can be enhanced, by the low refractive index layer.

In addition, in the present modification, in the case where the low refractive index layer is configured using a material having a refractive index higher than 0.3 and lower than 1.7, the critical angle at the interface of the low refractive index layer is reduced, to the light going from the light emitting layer 14 toward the low refractive index layer, and, therefore, the proportion in which the light going from the light emitting layer 14 toward the low refractive index layer is reflected at the interface of the low refractive index layer is enhanced, as compared to the case where the low refractive index layer is not provided. As a result, the proportion of evanescent deactivation of excitons due, for example, to surface plasmon in the vicinity of the anode 11 is lowered, and, therefore, the proportions of external release mode and the waveguide mode are increased. Accordingly, the injection or transport of holes into the light emitting layer 14 can be promoted and light extraction efficiency can be enhanced, by the low refractive index layer.

Besides, in the organic electroluminescence element 1 that emits red light according to the present modification, in the case where the refractive index of the low refractive index layer is 0.75 to 1.4, the proportion of the waveguide mode is high, and the external release mode becomes predominant over the evanescent mode. This ensures that the injection or transport of holes into the light emitting layer 14 can be promoted and light extraction efficiency can be enhanced.

In addition, in the organic electroluminescence element 1 that emits green light according to the present modification, in the case where the refractive index of the low refractive index layer is 0.5 to 1.7, the proportion of the waveguide mode is high. This ensures that the injection or transport of holes into the light emitting layer 14 can be promoted and light extraction efficiency can be enhanced.

Besides, in the organic electroluminescence element 1 that emits blue light according to the present modification, in the case where the refractive index of the low refractive index layer is 0.5 to 1.5, the proportion of the waveguide mode is high, and the proportion of the evanescent mode is not more than 50%. This ensures that the injection or transport of holes into the light emitting layer 14 can be promoted and light extraction efficiency can be enhanced.

### [Modification B]

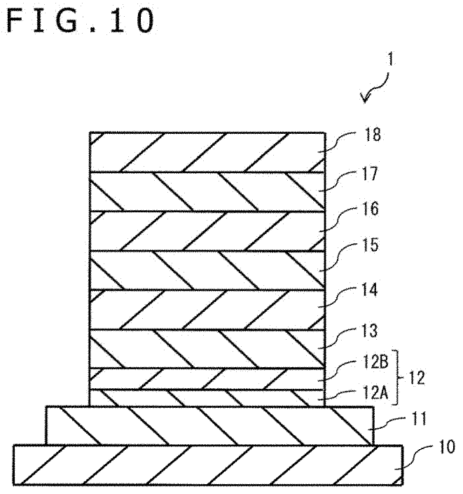

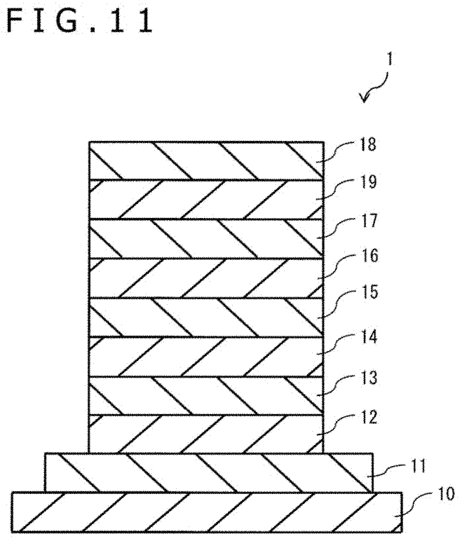

FIG. 10 depicts a modification of the sectional configuration of the organic electroluminescence element 1 according to the above embodiment and Modification A. In the organic electroluminescence element 1 according to the present modification, a hole injection layer 12 includes, for example, a metallic oxide layer 12A, and an organic matter layer 12B stacked on the metallic oxide layer 12A.

The metallic oxide layer 12A includes tungsten oxide (compositional formula: WOx, in which x is a real number in the range of generally 2<×<3). The film thickness of the metallic oxide layer 12A is not less than 2 nm, and is, for example, 10 nm. The metallic oxide layer 12A may contain such trace amounts of impurities as ordinarily allowed to mix in.

With the film thickness of the metallic oxide layer 12A set to be not less than 2 nm, it is easy to form a uniform tungsten oxide film, and it is easy to form Schottky ohmic connection between the anode 11 and the metallic oxide layer 12A described below. The Schottky ohmic connection is stably formed where the film thickness of the tungsten oxide film is not less than 2 nm. Therefore, when the tungsten oxide film is formed in a thickness larger than this value, a stable hole injection efficiency from the anode 11 into the metallic oxide layer 12A can be expected to be achieved utilizing the Schottky ohmic connection. Note that the “Schottky ohmic connection” means a connection in which the difference between the Fermi level of the anode 11 and the lowest binding energy of the occupied level in the vicinity of the Fermi surface of the metallic oxide layer 12A is not more than a predetermined value. The thickness of the metallic oxide layer 12A is, for example, 5 to 20 nm.

The organic matter layer 12B is formed in contact with the metallic oxide layer 12A. The organic matter layer 12B has an electron blocking property. The organic matter layer 12B is formed using an organic material such as a conductive polymer material. The organic matter layer 12B is formed, for example, by applying an organic polymer solution of a conductive polymer material such as PEDOT (a mixture of polythiophene and polystyrenesulfonic acid) to the metallic oxide layer 12A, followed by drying. In this case, the organic matter layer 12B includes a coating film. Further, for example, for solubility and an insolubilizing function, the organic matter layer 12B has a soluble group and an insolubilized group such as a thermal dissociation soluble group, a crosslinking group or a dissociable protective group, in its molecular structure. In other words, the organic matter layer 12B is an insolubilized layer.

The thickness of the organic matter layer 12B of the blue organic electroluminescence element 1 is preferably not less than 20 nm, for example, from the viewpoint of light emission efficiency. Note that from the viewpoint of chromaticity, the thickness of the organic matter layer 12B of the blue organic electroluminescence element 1 is preferably not less than 30 nm, for example. The thickness of the organic matter layer 12B of the green organic electroluminescence element 1 is preferably 10 to 20 nm, for example, from the viewpoint of light emission efficiency. The thickness of the organic matter layer 12B of the red organic electroluminescence element 12r is preferably not less than 30 nm, for example, from the viewpoint of light emission efficiency. From the viewpoint of shortening the film forming time, the thickness of the organic matter layer 12B of the red organic electroluminescence element 12r is preferably not more than 50 nm, for example.

### [Modification C]

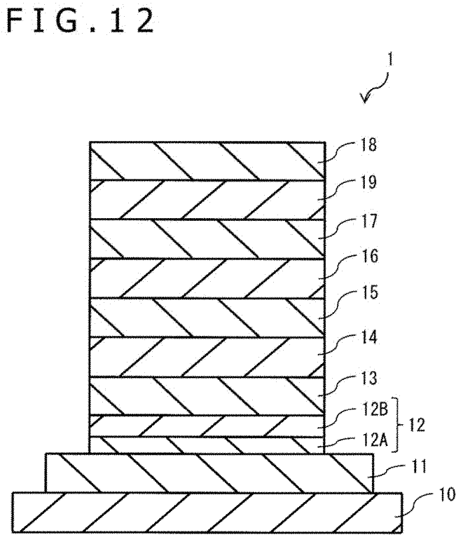

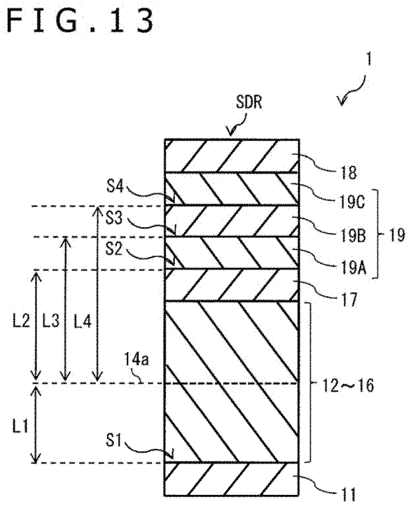

FIG. 11 depicts a modification of the sectional configuration of the organic electroluminescence element 1 according to the above embodiment and Modification A. FIG. 12 depicts a modification of the sectional configuration of the organic electroluminescence element 1 according to Modification B. An organic electroluminescence element 1 according to the present modification has a light distribution control layer 19, which makes contact with an upper surface of a cathode 17, between the cathode 17 and a sealing layer 18. As depicted in FIG. 13, the light distribution control layer 19 is a composite layer which includes, for example, light transmitting layers 19A, 19B and 19C stacked in this order from the cathode 17 side. The light transmitting layers 19A, 19B and 19C are formed, for example, using a transparent conductive material or a transparent dielectric material.

Examples of the transparent conductive material used for the light transmitting layers 19A, 19B and 19C include ITO and IZO. Examples of the transparent dielectric material used for the light transmitting layers 19A, 19B and 19C include silicon oxide (e.g., SiO₂), silicon oxynitride (e.g., SiON) and silicon nitride (e.g., SiN). The light transmitting layers 19A, 19B and 19C may have a function as a cathode 17, or may have a function as a passivation film. The light transmitting layers 19A, 19B and 19C may be formed using a low refractive index material such as, for example, MgF or NaF.

An anode 11 and the light transmitting layers 19A, 19B and 19C constitute a resonator structure. In the present modification, a sealing layer 18 also has a function of preventing external interference with the resonator structure configured between the anode 11 and the light transmitting layers 19A, 19B and 19C.

On an upper surface of the anode 11, a reflective surface S1 is formed by a refractive index difference between the anode 11 and a layer (a hole injection layer 12 or a hole transport layer 13) making contact with the upper surface of the anode 11. The reflective surface S1 is disposed at a position of an optical distance L1 from a light emission center 14a of a light emitting layer 14. The optical distance L1 is set in such a manner that the light of a center wavelength 2J of a light emission spectrum of the light emitting layer 14 is intensified by interference between the reflective surface S1 and the light emission center 14a. Specifically, the optical distance L1 is configured such as to satisfy the following expressions (1) and (2). Note that in the expressions (1) and (2), the unit of L1, λ1 and λ11 is nm.

(2L1/λ11)+(a1/2π)=m1 (1)

λ1−150<λ11<λ1+80 (2)

where

a1 is the phase change when the light emitted from the light emitting layer 14 is reflected on the reflective surface S1;

λ11 is a wavelength satisfying the expression (2); and

m1 is an integer of not less than 0.

In the above, al can be calculated using n0 and k of the complex refractive index N=n0−jk (n0: refractive index, k: extinction coefficient) of the anode 11 and the refractive index of the light emitting layer 14 (see, for example, Principles of Optics, Max Born and Emil Wolf, 1974 (PERGAMON PRESS) or the like). The complex refractive index of the anode 11 and the refractive index of the light emitting layer 14 can be measured using, for example, a spectroscopic ellipsometer.

If the value of m1 is high, a so-called microcavity (microscopic resonator) effect cannot be obtained, and, therefore, it is preferable that m1=0. For instance, the optical distance L11 preferably satisfies both of the following expressions (3) and (4). Note that in the expression (4), λ1=600 nm.

(2L1/λ11)+(a1/2π)=0 (3)

λ1−150 =450<λ11=600<λ1+80=680 (4)

Since the reflective surface S1 satisfying the expression (3) is provided at a position of zero-order interference, it indicates a high transmittance over a wide wavelength band. Therefore, as indicated in the expression (4), λ11 can be largely deviated from the center wavelength λ1.

On an upper surface of the cathode 17, a reflective surface S2 is formed by the refractive index difference between the cathode 17 and a layer (light transmitting layer 19A) making contact the upper surface of the cathode 17. The reflective surface S2 is disposed at a position of an optical distance L2 from the light emission center 14a of the light emitting layer 14. The optical distance L2 is set in such a manner that the light of the center wavelength 2J of the light emission spectrum of the light emitting layer 14 is intensified by interference between the reflective surface S2 and the light emission center 14a. Specifically, the optical distance L2 is configured such as to satisfy the following expressions (5) and (6). Note that in the expressions (5) and (6), the unit of L2, λ1 and λ12 are nm.

(2L2/λ12)+(a2/2π)=m2 (5)

λ1−80<λ12<λ1+80 (6)

where

a2 is the phase change when the light emitted from the light emitting layer 14 is reflected on the reflective surface S2;

λ12 is a wavelength satisfying the expression (6); and

m2 is an integer of not less than 0.

In the above, a2 can be calculated using n0 and k of the complex refractive index N=n0−jk (n0: refractive index, k: extinction coefficient) of the light transmitting layer 19A and the refractive index of the light emitting layer 14. The complex refractive index of the light transmitting layer 19A and the refractive index of the light emitting layer 14 can be measured using, for example, a spectroscopic ellipsometer.

If the value of m2 is high, the so-called microcavity (microscopic resonator) effect cannot be obtained, and, therefore, it is preferable that m2=1.

Each of the reflective surfaces S1 and S2 is configured such that the light generated in the light emitting layer 14 is intensified between itself and the light emission center 14a. Due to this amplifying effect, a peak of transmittance is generated in the vicinity of 620 nm.

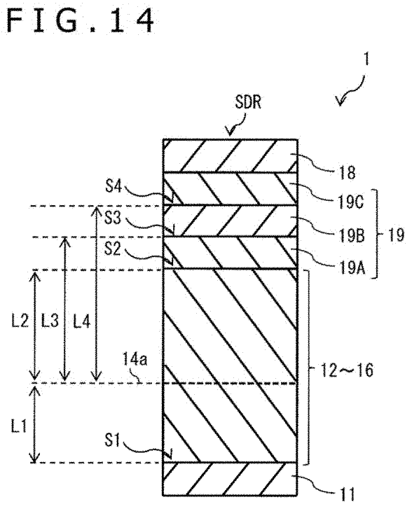

Note that, for example, as depicted in FIG. 14, the cathode 17 may not be provided, the light transmitting layer 19A may be provided with the role of the cathode 17, and the reflective surface S2 may be formed by the refractive index difference between the electron transport layer 15 or the electron injection layer 16 and the light transmitting layer 19A.

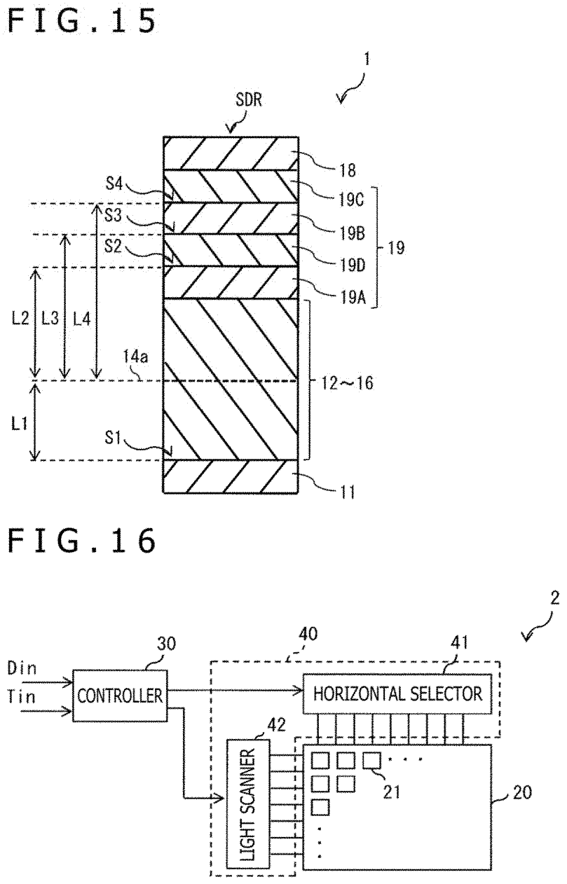

In addition, for example as depicted in FIG. 15, a light transmitting layer 19D may be provided between the light transmitting layer 19A and the light transmitting layer 19B, and a reflective surface S2 may be formed by the refractive index difference between the light transmitting layer 19D and the light transmitting layer 19A.

On an upper surface of the light transmitting layer 19A, a reflective surface S3 is formed by the refractive index difference between the light transmitting layer 19A and a layer (light transmitting layer 19B) making contact with the upper surface of the light transmitting layer 19A. The reflective surface S3 is disposed at a position of an optical distance L3 from the light emission center 14a of the light emitting layer 14. In the organic electroluminescence element 1 that emits red light, the optical distance L3 is set in such a manner that the light of the center wavelength λ1 (λ1R) of the light emission spectrum of the light emitting layer 14 is weakened by interference between the reflective surface S3 and the light emission center 14a. In the organic electroluminescence element 1 that emits blue light, the optical distance L3 is set in such a manner that the light of the center wavelength λ1 (λ1B) of the light emission spectrum of the light emitting layer 14 is intensified by interference between the reflective surface S3 and the light emission center 14a. Specifically, in the organic electroluminescence element 1 that emits red light, the optical distance L3 is configured such as to satisfy the following expressions (7) and (8). In the organic electroluminescence element 1 that emits blue light, the optical distance L3 is configured such as to satisfy the following expressions (9) and (10). Note that in the expressions (7), (8), (9) and (10), the unit of L3, λ1, λ13 and λ23 is nm.

(2L3/λ13)+(a3/2π)=m3+1/2 (7)

λ1R−150<λ13<λ1R+150 (8)

(2L3/λ23)+(a3/2π)=n3 (9)

λ1B=150<λ23<λ1B+150 (10)

where

a3 is the phase change when the light emitted from the light emitting layer 14 is reflected on the reflective surface S3;

λ13 is a wavelength satisfying the expression (8);

λ23 is a wavelength satisfying the expression (10); and

m3 and n3 are each an integer of not less than 0.

On an upper surface of the light transmitting layer 19B, a reflective surface S4 is formed by the refractive index difference between the light transmitting layer 19B and a layer (light transmitting layer 19C) making contact with the upper surface of the light transmitting layer 19B. The reflective surface S4 is disposed at a position of an optical distance L4 from the light emission center 14a of the light emitting layer 14. In the organic electroluminescence element 1 that emits red light, the optical distance L4 is set in such a manner that the light of the center wavelength 2J (2JR) of the light emission spectrum of the light emitting layer 14 is weakened by interference between the reflective surface S4 and the light emission center 14a. In the organic electroluminescence element 1 that emits blue light, the optical distance L4 is set in such a manner that the light of the center wavelength λ1 (λ1B) of the light emission spectrum of the light emitting layer 14 is intensified by interference between the reflective surface S4 and the light emission center 14a. Specifically, in the organic electroluminescence element 1 that emits red light, the optical distance L4 is configured such as to satisfy the following expressions (11) and (12). In the organic electroluminescence element 1 that emits blue light, the optical distance L4 is configured such as to satisfy the following expressions (13) and (14). Note that in the expressions (11), (12), (13) and (14), the unit of L4, λ1, λ14 and λ24 is nm.

(2L4/λ14)+(a4/2π)=m4+1/2 (11)

λ1R−150<λ14<+150 (12)

(2L4/λ24)+(a3/2π)=n4 (13)

λ1B−150<λ24<λ1B+150 (14)

where

a4 is the phase change when the light emitted from the light emitting layer 14 is reflected on the reflective surface S4;

λ14 is a wavelength satisfying the expression (11);

λ24 is a wavelength satisfying the expression (13); and

m4 and n4 are each an integer of not less than 0.

In the above, a3 can be calculated using n0 and k of the complex refractive index N=n0−jk (n0: refractive index, k: extinction coefficient) of the light transmitting layer 19B and the refractive index of the light emitting layer 14. Similarly, a4 can be calculated using n0 and k of the complex refractive index N=n0−jk (n0: refractive index, k: extinction coefficient) of the light transmitting layer 19C and the refractive index of the light emitting layer 14. The complex refractive indexes of the light transmitting layers 19B and 19C and the refractive index of the light emitting layer 14 can be measured using, for example, a spectroscopic ellipsometer.

Though details will be described later, since the reflection conditions on the reflective surfaces S3 and S4 can thus be made different for the organic electroluminescence element 1 that emits red light and the organic electroluminescence element 1 that emits blue light, light emission state can be adjusted on the basis of the light emission color of the organic electroluminescence element 1.

With the reflection on the reflective surface S3 added, the light generated in the red light emitting layer 14 is weakened, and the half-value width of spectrum is broadened. In addition, with the reflection on the reflective surface S4 added, the light generated in the red light emitting layer 14 is further weakened, and the half-value width of spectrum is further broadened. With the vicinity of a peak of the spectrum thus made gently sloped, sudden variations in luminance and hue with angle can be restrained. Besides, with the reflection on the reflective surface S4 added, the light generated in the blue light emitting layer 14 is intensified, and a peak is enlarged. With a steep peak thus provided, light extraction efficiency can be enhanced. In addition, chromaticity point can also be enhanced. The positions of peaks of spectra formed by the reflective surfaces S1 and S2 and the positions of peaks of spectra formed by the reflective surfaces S3 and S4 may be matched to each other, or may be deviated from each other. In the case where the positions of peaks of spectra formed by the reflective surfaces S1 and S2 and the positions of peaks of spectra formed by the reflective surfaces S3 and S4 are deviated from each other, a wavelength band in which the effect of a resonator structure is obtained can be enlarged, and steep variations in luminance and hue can be restrained.

The organic electroluminescence element 1 that emits green light has, for example, the reflective surfaces S1 to S4 configured similarly to those of the organic electroluminescence element 1 that emits blue light. Specifically, the reflective surfaces S1 to S4 are configured in such a manner as to intensify the light with respect to the center wavelength of light emission spectrum of the green light emitting layer 14.

Operation and effect of the organic electroluminescence element 1 according to the present modification will be described below. In the present modification, the light emitted from the light emitting layer 14 undergoes multiple reflections between the reflective surface S1 and the reflective surface S4, before being extracted via a light extraction surface SDR. Meanwhile, in a general organic electroluminescence device, it is not easy to enhance light distribution characteristics.

For example, there has been proposed a method in which the film thickness between a light transmitting electrode and a reflective electrode is set such as to permit resonance of light of a desired wavelength, thereby enhancing light emission efficiency (see, for example, WO 01/039554). In addition, an attempt to control the balance of attenuation of the three primary colors (red, green and blue) by, for example, controlling the film thicknesses of organic layers, to thereby enhance viewing angle characteristics of chromaticity point of white color (see, for example, JP 2011-159433A).

In these configurations, however, a stacked structure of the organic electroluminescence element functions as an interference filter having a narrow half-value width, for the spectrum of the light extracted. Therefore, when a light extraction surface is viewed obliquely, the wavelength of light is largely shifted. Accordingly, a lowering in light emission intensity or the like is generated depending on the viewing angle, and viewing angle dependency is increased.

Besides, for example, JP 2006-244713A proposes a structure for reducing variations in hue with viewing angle. However, although it may be possible to apply this structure to monochrome and to reduce the viewing angle dependency of luminance, it is difficult to apply this structure to a sufficiently wide wavelength band. Although it may be contemplated to enhance reflectance in order to widen the wavelength band to which this structure is applicable, such an approach leads to a conspicuous lowering in light extraction efficiency.

While a method of reducing the viewing angle dependency by adjusting the positional relation in the stacked structure of the organic electroluminescence element, light emission position or the like may be contemplated, the adjustment in this method may be difficult to accomplish, for example, in the case where wavelength dispersion of refractive index is generated due to the spectra of lights emitted from the light emitting layers. In the wavelength dispersion of refractive index, the refractive indexes of constituent materials differ depending on the wavelength, and, therefore, differences in the effect of a resonator structure are generated between the red organic electroluminescence element, the green organic electroluminescence element and the blue organic electroluminescence element. For instance, in the red organic electroluminescence element, the peak of the red light extracted is too steep, whereas in the blue organic electroluminescence element, the peak of the blue light extracted is too gently sloped. If the effect of the resonator structure thus differs largely on the basis of element region, angle dependencies of luminance and hue are enlarged, and light distribution characteristic is lowered.

On the other hand, in the present modification, the influence of the reflective surfaces S3 and S4 on the light generated in the red light emitting layer 14 and the influence of the reflective surfaces S3 and S4 on the light generated in the blue light emitting layer 14 are different from each other. Specifically, the light generated in the red light emitting layer 14 and the light generated in the blue light emitting layer 14 become as follows.

The light generated in the red light emitting layer 14 is weakened by interference between the light emission center 14a of the red light emitting layer 14 and the reflective surfaces S3 and S4 of the red sub-pixel 22R. On the other hand, the light generated in the blue light emitting layer 14 is intensified by interference between the light emission center 14a of the blue light emitting layer 14 and the reflective surfaces S3 and S4 of the blue organic electroluminescence element 1.

As a result, in the red organic electroluminescence element 1, red light in which the vicinity of a peak is gently sloped is extracted via the light extraction surface SDR, whereas in the blue organic electroluminescence element 1, blue light having a steep peak is extracted via the light extraction surface SDB. Therefore, the difference between the effect of the resonator structure of the red organic electroluminescence element 1 and the effect of the resonator structure of the blue organic electroluminescence element 1 is reduced, so that viewing angle dependencies of luminance and hue are reduced. Accordingly, light distribution characteristics can be enhanced. In addition, the organic electroluminescence device 2 having high light distribution characteristics is preferably applicable also to a display device requiring high image quality, so that productivity of display device can be enhanced. In the organic electroluminescence element 1 according to the present modification, Δuv≤0.015 and a luminance of not less than 60% can be maintained even at a viewing angle of 45°, and high image quality can be realized.

As above-mentioned, in the organic electroluminescence element 1 according to the present modification, the reflective surfaces S3 and S4 of the red sub-pixel 22R are provided such as to weaken the light generated in the red light emitting layer 14, whereas the reflective surfaces S3 and S4 of the blue sub-pixel 22B are provided such as to intensify the light generated in the blue light emitting layer 14. As a result, the effect of the resonator structure can be adjusted on a sub-pixel 22 basis, and, therefore, light distribution characteristics can be enhanced.

In addition, since a high light transmittance can be obtained over a wide wavelength band, light extraction efficiency can be enhanced. As a result, power consumption can also be suppressed.

Note that in the case where the reflective surfaces S3 and S4 are formed by stacking metal thin films having a thickness of not less than 5 nm, a high light transmittance can be obtained over a wide wavelength band.

Besides, the organic electroluminescence element 1 according to the present modification is preferable for the case where the light emitting layers 14 are printed layers. The light emitting layers 14 are, by passing through a drying process, for example, susceptible to generation of variations in thickness depending on regions. In other words, the light emitting layers 14 are susceptible to generation of a film thickness distribution. In the organic electroluminescence element 1 according to the present modification, the difference in the effect of the resonator structure on the organic electroluminescence element 1 basis due to the film thickness distribution can be adjusted.

### 3. SECOND EMBODIMENT

### [Configuration]

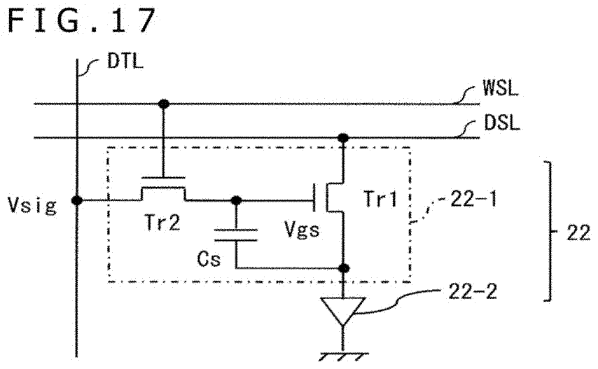

FIG. 16 depicts a general configuration example of an organic electroluminescence device 2 according to a second embodiment of the present disclosure. FIG. 17 depicts an example of circuit configuration of a sub-pixel 22 included in each pixel 21 provided in the organic electroluminescence device 2. The organic electroluminescence device 2 includes, for example, an organic electroluminescence panel 20, a controller 30 and a driver 40. The driver 40 is mounted, for example, at an outer edge portion of the organic electroluminescence panel 20. The organic electroluminescence panel 20 has a plurality of pixels 21 arranged in a matrix pattern. The controller 30 and the driver 40 drive the organic electroluminescence panel 20 (the plurality of pixels 21), based on a video signal Din and a synchronizing signal Tin inputted externally.

### (Organic Electroluminescence Panel 20)

The organic electroluminescence panel 20 has the pixels 21 subjected to active matrix driving by the controller 30 and the driver 40, thereby displaying an image based on the video signal Din and the synchronizing signal Tin which are externally inputted. The organic electroluminescence panel 20 includes a plurality of scanning lines WSL extending in a row direction, a plurality of signal lines DTL and a plurality of power source lines DSL extending in a column direction, and the plurality of pixels 21 arranged in a matrix pattern.

The scanning lines WSL are used for selection of each of the pixels 21, and supply the pixels 21 with selection pulses for selecting the pixels 21 on the basis of a predetermined unit (for example, pixel row). The signal lines DTL are used for supplying the pixels 21 with signal voltages Vsig according to the video signal Din, and supply the pixels 21 with data pulses including the signal voltages Vsig. The power source lines DSL supply the pixels 21 with electric power.

Each of the pixels 21 includes, for example, a sub-pixel 22 that emits red light, a sub-pixel 22 that emits green light, and a sub-pixel 22 that emits blue light. Note that each pixel 21 may further include, for example, a sub-pixel 22 that emits light in other color (for example, white or yellow). In each pixel 21, the plurality of sub-pixels 22 are disposed, for example, in a line in a predetermined direction.

Each of the signal lines DTL is connected to an output end of a horizontal selector 41 which will be described later. The plurality of signal lines DTL are assigned, for example, one to each pixel column. Each of the scanning lines WSL is connected to an output end of a light scanner 42 which will be described later. The plurality of scanning lines WSL are assigned, for example, one to each pixel row. Each of the power source lines DSL is connected to an output end of a power source. The plurality of power source lines DSL are assigned, for example, one to each pixel row.

Each of the sub-pixels 22 includes a pixel circuit 22-1 and an organic electroluminescence element 22-2. The organic electroluminescence element 22-2 is the organic electroluminescence element 1 according to the above-described first embodiment, Modification A and Modification B.

The pixel circuit 22-1 controls light emission and quenching of the organic electroluminescence element 22-2. The pixel circuit 22-1 has a function of holding a voltage written into each sub-pixel 22 by write scanning which will be described later. The pixel circuit 22-1 includes, for example, a driving transistor Tr1, a writing transistor Tr2 and a storage capacitor Cs.

The writing transistor Tr2 controls the application of the signal voltage Vsig corresponding to the video signal Din to a gate of the driving transistor Tr1.

Specifically, the writing transistor Tr2 samples voltages on the signal lines DTL, and writes a voltage obtained by sampling into the gate of the driving transistor Tr1. The driving transistor Tr1 is connected in series with the organic electroluminescence element 22-2. The driving transistor Tr1 drives the organic electroluminescence element 22-2. The driving transistor Tr1 controls a current flowing in the organic electroluminescence element 22-2 according to the magnitude of the voltage sampled by the writing transistor Tr2. The storage capacitor Cs is for holding a predetermined voltage between the gate and the source of the driving transistor Tr1. The storage capacitor Cs has a role of keeping constant a gate-source voltage Vgs of the driving transistor Tr1 during a predetermined period. Note that the pixel circuit 22-1 may have a circuit configuration obtained by adding various capacitors and transistors to the above-mentioned 2Tr1 C circuit, or may have a circuit configuration different from the 2Tr1 C circuit configuration.

Each signal line DTL is connected to an output end of the horizontal selector 41 which will be described later and to the source or drain of the writing transistor Tr2. Each scanning line WSL is connected to an output end of the light scanner 42 which will be described later and to the gate of the writing transistor Tr2. Each power source line DSL is connected to a power source circuit and to the source or drain of the driving transistor Tr1.

The gate of the writing transistor Tr2 is connected with the scanning line WSL. The source or drain of the writing transistor Tr2 is connected with the signal line DTL. That terminal of the source and the drain of the writing transistor Tr2 which is not connected with the signal line DTL is connected to the gate of the driving transistor Tr1. The source or the drain of driving transistor Tr1 is connected with the power source line DSL. That terminal of the source and the drain of the driving transistor Tr1 which is not connected with the power source line DSL is connected to the anode 11 of the organic electroluminescence element 21-2. One end of the storage capacitor Cs is connected to the gate of the driving transistor Tr1. The other end of the storage capacitor Cs is connected to that terminal of the source and the drain of the driving transistor Tr1 which is located on the organic electroluminescence element 21-2 side.

### (Driver 40)

The driver 40 includes, for example, the horizontal selector 41 and the light scanner 42. The horizontal selector 41 applies the analog signal voltage Vsig, inputted from the controller 30, to each signal line DTL according to (synchronously with) the inputting of a control signal, for example. The light scanner 42 scans the plurality of sub-pixels 22 on the basis of a predetermined unit.

### (Controller 30)

The controller 30 will be described below. The controller 30 applies predetermined correction to the digital video signal Din inputted externally, for example, and generates the signal voltage Vsig, based on the video signal obtained by the correction. The controller 30 outputs the generated signal voltage Vsig, for example, to the horizontal selector 41. The controller 30 outputs a control signal to each circuit in the driver 40, according to (synchronously with) the synchronizing signal Tin inputted externally, for example.

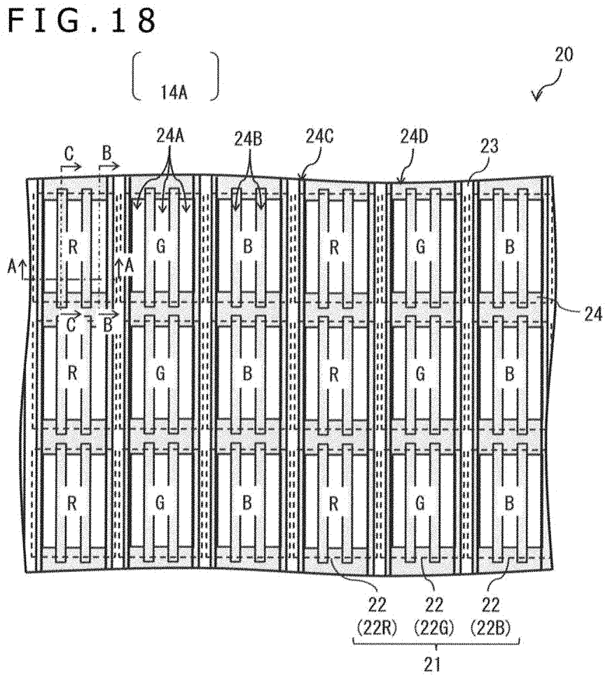

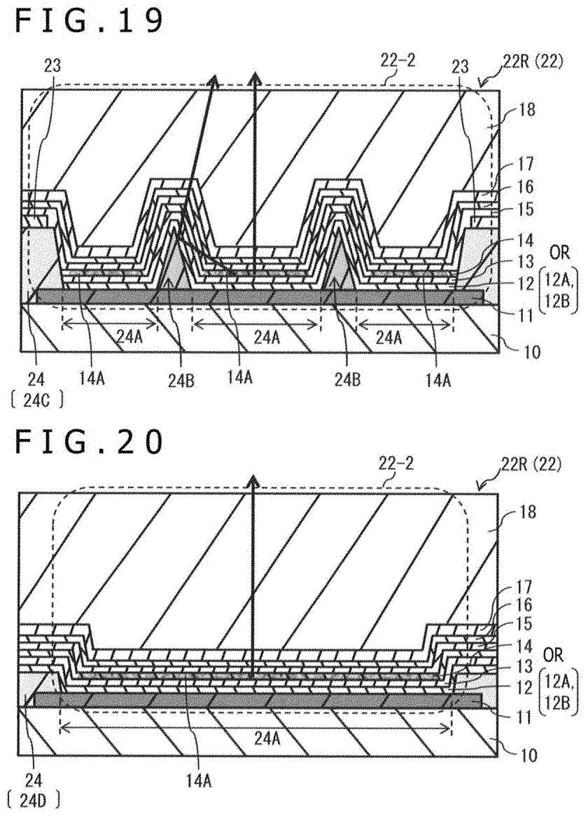

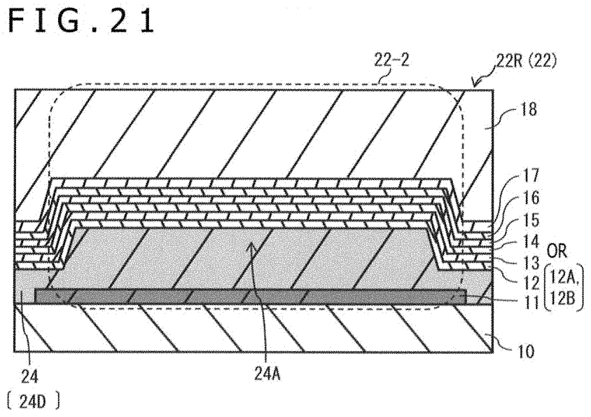

Referring to FIGS. 18, 19, 20 and 21, the organic electroluminescence element 22-2 will be described below. FIG. 18 depicts a general configuration example of the organic electroluminescence panel 20. FIG. 19 depicts a sectional configuration example, along line A-A, of the organic electroluminescence panel 20 of FIG. 14 (namely, a sectional configuration example in the row direction of the sub-pixel 22 (22R)). FIG. 20 depicts a sectional configuration example, along line B-B, of the organic electroluminescence panel 20 of FIG. 18 (namely, a sectional configuration example in the column direction of the sub-pixel 22 (22R)). FIG. 21 depicts a sectional configuration example, along line C-C, of the organic electroluminescence panel 20 of FIG. 18 (namely, a sectional configuration example in the column direction of the sub-pixel 22 (22R)). Note that in FIG. 20 is illustrated a sectional configuration example at a part avoiding a crosspiece section 24B which will be described later. In FIG. 21 is illustrated a sectional configuration example at a part including the crosspiece section 24B.

The organic electroluminescence panel 20 has the plurality of pixels 21 arranged in a matrix pattern. Each of the pixels 21 includes, for example, as aforementioned, the sub-pixel 22 (22R) that emits red light, the sub-pixel 22 (22G) that emits green light, and the sub-pixel 22 (22B) that emits blue light.

The sub-pixel 22R includes an organic electroluminescence element 22-2 (22r) that emits red light. The sub-pixel 22G includes an organic electroluminescence element 22-2 (22g) that emits green light. The sub-pixel 22B includes an organic electroluminescence element 22-2 (22b) that emits blue light. The sub-pixels 22R, 22G and 22B are arranged, for example, in a pattern of stripes. In each pixel 21, the sub-pixels 22R, 22G and 22B are aligned in the row direction, for example. Further, in each pixel row, the plurality of sub-pixels 22 that emits light in the same color are aligned in the column direction, for example.

The organic electroluminescence panel 20 has a substrate 10. The substrate 10 includes, for example, a base material that supports the organic electroluminescence elements 22-2, the insulating layer 24 and the line banks 23, and a wiring layer provided over the base material. The base material in the substrate 10 is formed using, for example, non-alkali glass, soda glass, nonfluorescent glass, phosphate glass, borate glass, quartz or the like. The base material in the substrate 10 may be formed using, for example, acrylic resin, styrene resin, polycarbonate resin, epoxy resin, polyethylene, polyester, silicone resin, or alumina or the like. The wiring layer in the substrate 10 is formed, for example, with the pixel circuits 22-1 of the pixels 21.

The organic electroluminescence panel 20 further includes the insulating layer 24 over the substrate 10. The insulating layer 24 is for partitioning the sub-pixels 22. An upper limit for the thickness of the insulating layer 24 is preferably in such a range that shape control can be made on a manufacturing basis, from the viewpoint of control of variability in film thickness and bottom line width, and is preferably not more than 10 μm. In addition, the upper limit for the thickness of the insulating layer 24 is preferably in such a range that an increase in tact due to an increase in exposure time in an exposure process can be restrained and that a lowering in productivity in a mass production process can be restrained, and is more preferably not more than 7 μm. Besides, a lower limit for the thickness of the insulating layer 24 is determined by a resolution limit concerning an exposure apparatus and materials, since the bottom line width should be supplemented to substantially the same with the film thickness as the film thickness decreases. The lower limit for the thickness of the insulating layer 24 is preferably not less than 1 μm, in the case of using a semiconductor stepper, and is preferably not less than 2 μm, in the case of using a stepper and a scanner for flat panels. Therefore, the thickness of the insulating layer 24 is preferably 1 to 10 μm, and more preferably 2 to 7 μm.

The insulating layer 24 includes a plurality of column restricting sections 24C and a plurality of row restricting sections 24D that partition the sub-pixels 22. Each column restricting section 24C extends in the column direction, and each row restricting section 24D extends in the row direction. The plurality of column restricting sections 24C extend in the column direction, and are aligned in parallel at a predetermined spacing in the row direction. The plurality of row restricting sections 24D extend in the row direction, and are aligned in parallel at a predetermined spacing in the column direction. The plurality of column restricting sections 24C and the plurality of row restricting sections 24D are intersecting (for example, orthogonally intersecting) each other, in a grid layout as a whole. Each sub-pixel 22 is surrounded by two adjacent column restricting sections 24C and two adjacent row restricting sections 24D, whereby each sub-pixel 22 is partitioned.

The insulating layer 24 includes, for each sub-pixel 22, a plurality of (for example, two) crosspiece sections 24B extending in the column direction. The plurality of crosspiece sections 24B extend in the column direction and are aligned in parallel at a predetermined spacing in the row direction. Further, the insulating layer 24 includes a plurality of (for example, three) slit-shaped openings 24A at that part in the region surrounded by two adjacent column restricting sections 24C and two adjacent row restricting sections 24D at which the crosspiece section 24B is not formed. At a bottom surface of each opening 24A, a surface of the anode 11 which will be described later is exposed. Therefore, holes supplied from the anode 11 exposed at the bottom surface of each opening 24A and electrons supplied from a cathode 17 which will be described later re-combine each other in the light emitting layer 14 which will be described later, whereby light emission is generated in the light emitting layer 14 which will be described. Therefore, of the light emitting layer 14 described later, a region facing the opening 24A is a light emitting region 14A.

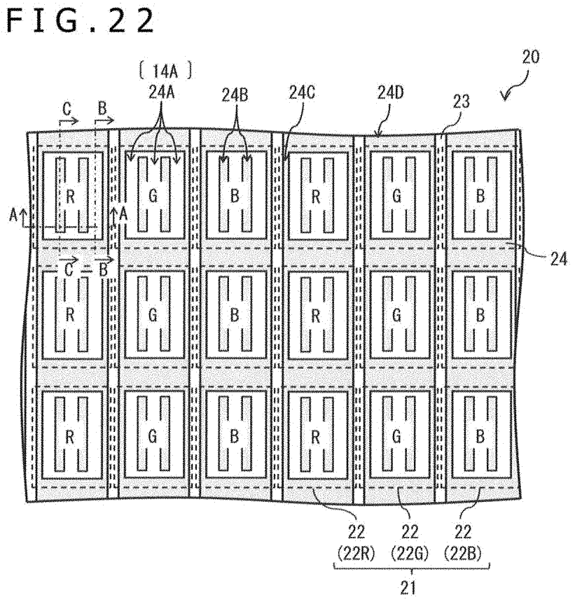

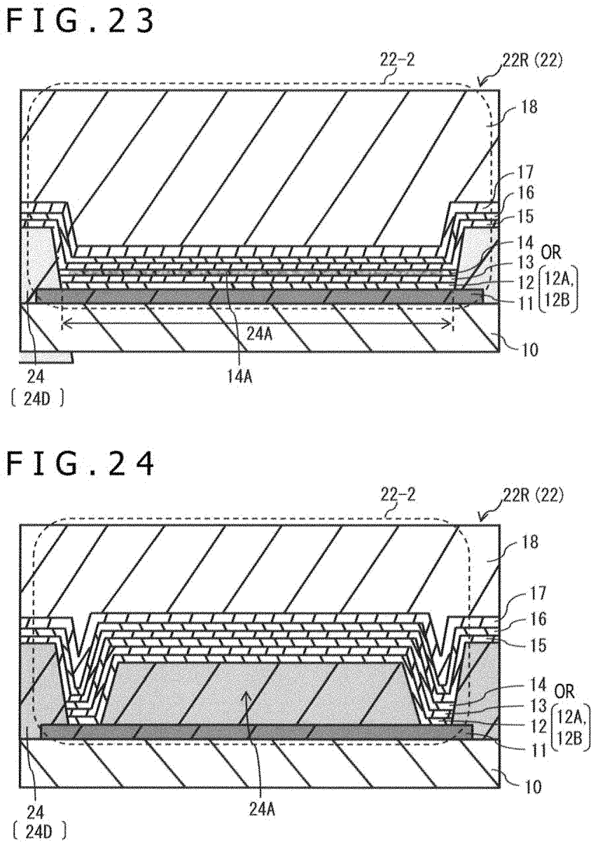

For example, as depicted in FIGS. 18 to 21, each of the crosspiece sections 24B may be formed such as to range over the two adjacent row restricting sections 24D, or, for example, as depicted in FIGS. 22 to 24, each crosspiece section 24B may be formed at a part spaced from the two adjacent row restricting sections 24D. FIG. 22 depicts a general configuration example of the organic electroluminescence panel 20. FIG. 23 depicts a sectional configuration example, along line B-B, of the organic electroluminescence panel 20 of FIG. 22 (namely, a sectional configuration example in the column direction of the sub-pixel 22 (22R)). FIG. 24 depicts a sectional configuration example, along line C-C, of the organic electroluminescence panel 20 of

FIG. 22 (namely, a sectional configuration example in the column direction of the sub-pixel 22 (22R)). Note that a sectional configuration example, along line A-A, of the organic electroluminescence panel 20 of FIG. 22 (namely, a sectional configuration example in the row direction of the sub-pixel 22 (22R)) is in common with FIG. 19 above.

The height of the row restricting sections 24D is smaller than the height of the column restricting sections 24C as depicted in FIGS. 18 to 21, for example. In this instance, the plurality of sub-pixels 22 aligned in the column direction ae disposed in belt-shaped groove sections formed by the left and right two column restricting sections 24C of these sub-pixels 22, and share, for example, the light emitting layer 14, the electron transport layer 15 and the electron injection layer 16. Note that the plurality of sub-pixels 22 aligned in the column direction may share, for example, the hole injection layer 12, the hole transport layer 13, the light emitting layer 14, the electron transport layer 15 and the electron injection layer 16. Note that the height of the row restricting sections 24D may be the same as the height of the column restricting sections 24C, as depicted in FIGS. 22 to 24 and FIG. 19, for example. In this instance, the sub-pixels 22 are each disposed in a hollow formed by the two adjacent column restricting sections 24C and the two adjacent row restricting sections 24D, and, for example, have individually separate light emitting layers 14.

The section in the row direction of each opening 24A is a trapezoid upwardly enlarged in width as depicted in FIG. 19, for example. In addition, the section in the column direction of each opening 24A is a trapezoid upwardly enlarged in width as depicted in FIGS. 20 and 23, for example. Specifically, side surfaces of each opening 24A is of a reflector structure for building up the light generated from the light emitting layer 14 which will be described later. Let the refractive index of the sealing layer 18 be n₁ and let the refractive index of the insulating layer 24 be n₂, then n₁ and n₂ satisfy the following expressions (15) and (16). Here, n₂ is preferably 1.4 to 1.6. As a result, efficiency of extraction to the exterior of the light generated from the light emitting layer 14 which will be described later is enhanced.

1.1≤n₁≤1.8 (15)

|n₁−n₂|≥0.20 (16)

In addition, further, the depth D of the openings 24A (namely, the thickness of the insulating layer 24), the opening width Wh on the upper surface side of the insulating layer 24, and the opening width WL on the upper surface side of the insulating layer 24 preferably satisfy the following expressions (17) and (18).

0.5≤WL/Wh≤0.8 (17)

0.5≤D/WL≤2.0 (18)

With such shapes and refractive index conditions, the efficiency of extraction of light from the light emitting layer 14 can be enhanced by the reflector structure owing to the opening 24A of the insulating layer 24. As a result, according to the present inventors' investigations, the luminance per sub-pixel 22 can be increased to 1.2 to 1.5 times that in the case where the reflector structure is not provided.

The insulating layer 24 is formed using, for example, an insulating organic material. Examples of the insulating organic material include acrylic resins, polyimide resins, and novolak type phenolic resins. The insulating layer 24 is preferably formed using, for example, an insulating resin having heat resistance and solvent resistance. The column restricting sections 24C and the row restricting sections 24D are formed, for example, by processing the insulating resin into a desired pattern by photolithography and development. The sectional shape of the column restricting section 24C is, for example, of a normally tapered form, as depicted in FIG. 19. The sectional shape of the row restricting section 24D is, for example, of a normally tapered form, as depicted in FIG. 20.

In the present embodiment, the organic electroluminescence element 1 according to the first embodiment, Modification A and Modification B is used as the organic electroluminescence element 22-2 of each sub-pixel 22. As a result, it is possible to realize the organic electroluminescence panel 20 and the organic electroluminescence device 2 which are high in light extraction efficiency.

### 4. MODIFICATION OF SECOND EMBODIMENT

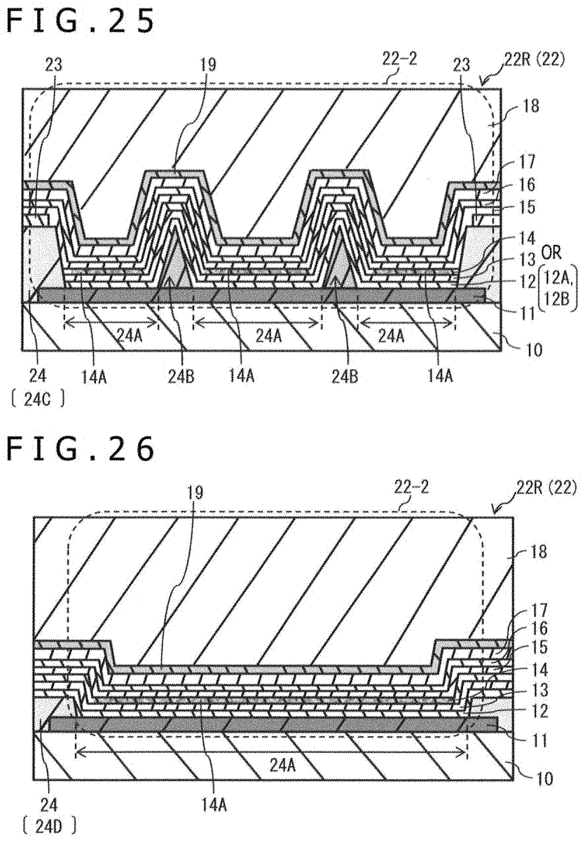

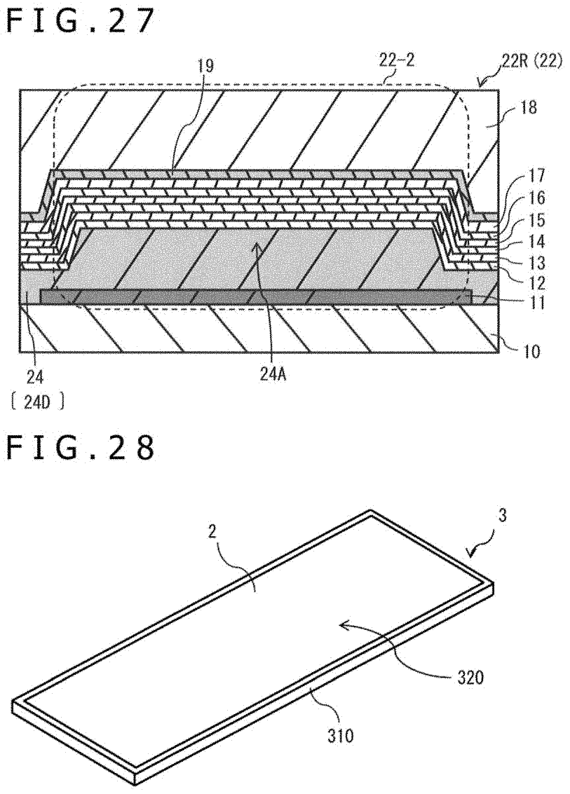

In the second embodiment, each organic electroluminescence element 22-2 may include a light distribution control layer 19 over the cathode 17, as depicted in FIGS. 25, 26 and 27, for example. Note that FIG. 25 depicts a sectional configuration example, along line A-A, of the organic electroluminescence panel 20 of FIG. 18 (namely, a sectional configuration example in the row direction of the sub-pixel 22 (22R)). FIG. 26 depicts a sectional configuration example, along line B-B, of the organic electroluminescence panel 20 of FIG. 18 (namely, a sectional configuration example in the column direction of the sub-pixel 22 (22R)). FIG. 27 depicts a sectional configuration example, along line C-C, of the organic electroluminescence panel 20 of FIG. 18 (namely, a sectional configuration example in the column direction of the sub-pixel 22 (22R)).

In the present modification, the light distribution control layer 19 is provided, for example, between the cathode 17 and the sealing layer 18. The light distribution control layer 19 may be formed, for example, in contact with the whole part of the surface of the cathode 17.

In the present modification, the influence of the reflective surfaces S3 and S4 on the light generated in the red light emitting layer 14 and the influence of the reflective surfaces S3 and S4 on the light generated in the blue light emitting layer 14 are different from each other. Specifically, the light generated in the red light emitting layer 14 and the light generated in the blue light emitting layer 14 become as follows.

The light generated in the red light emitting layer 14 is weakened by interference between the light emission center 14a of the red light emitting layer 14 and the reflective surfaces S3 and S4 of the red sub-pixel 22R. On the other hand, the light generated in the blue light emitting layer 14 is intensified by interference between the light emission center 14a of the blue light emitting layer 14 and the reflective surfaces S3 and S4 of the blue organic electroluminescence element 1.

As a result, in the red organic electroluminescence element 1, red light with the vicinity of a peak gently sloped is extracted via the light extraction surface SDR, whereas in the blue organic electroluminescence element 1, blue light with a steep peak is extracted through the light extraction surface SDB. Therefore, the difference between the effect of the resonator structure of the red organic electroluminescence element 1 and the effect of the resonator structure of the blue organic electroluminescence element 1 is reduced, so that angle dependencies of luminance and hue are reduced. Accordingly, light distribution characteristics can be enhanced. In addition, the organic electroluminescence device 2 having high light distribution characteristics is preferable also for a display device requiring high image quality, and productivity of the display device can be enhanced.

### 5. APPLICATION EXAMPLES

### Application Example 1

Hereinafter, an application example of the organic electroluminescence device 2 according to the above-described second embodiment and modifications will be described. The organic electroluminescence device 2 according to the above second embodiment and modifications is applicable to display devices of electronic apparatuses in any field in which a video signal inputted externally or a video signal generated internally is displayed as an image or a video image, such as television sets, digital cameras, notebook type personal computers, sheet-shaped personal computers, portable terminal devices such as mobile phones, and video cameras.

FIG. 28 depicts the external appearance of an electronic apparatus 3 according to the present application example, as viewed obliquely. The electronic apparatus 3 is, for example, a sheet-shaped personal computer including a display surface 320 at a main surface of a housing 310. The electronic apparatus 3 has the organic electroluminescence device 2 according to the above second embodiment and its modifications at the display surface 320 of the electronic apparatus 3. The organic electroluminescence device 2 according to the second embodiment and its modifications is disposed with the organic electroluminescence panel 20 directed to the outside. In the present application example, since the organic electroluminescence device 2 according to the above second embodiment and its modifications is provided at the display surface 320, an electronic apparatus 3 high in light emission efficiency can be realized.

### Application Example 2

Hereinafter, an application example of the organic electroluminescence element 22-2 according to the above-described second embodiment and its modifications will be described. The organic electroluminescence element 22-2 according to the above second embodiment and its modifications is applicable to light sources of illumination devices in any field, such as desk or floor type illumination devices or room illumination devices.

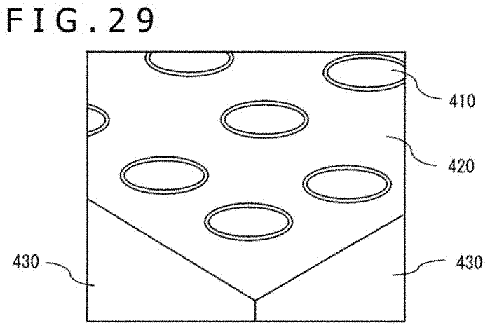

FIG. 29 depicts the external appearance of a room illumination device to which the organic electroluminescence element 22-2 according to the second embodiment and its modifications is applied. This illumination device has, for example, an illuminating section 410 including one or a plurality of organic electroluminescence elements 22-2 according to the second embodiment and its modifications. The illuminating sections 410 are disposed in an appropriate number and at appropriate intervals on a ceiling 420 of a building. Note that the illuminating sections 410 may be disposed, according to the use, in any places such as a wall 430 or a floor (not illustrated) as well as on the ceiling 420.

In these illumination devices, illumination is performed by light from the organic electroluminescence element 22-2 according to the second embodiment and its modifications. As a result, an illumination device high in light emission efficiency can be realized.

While the present disclosure has been described above by embodiments thereof, the present disclosure is not limited to the embodiments, and various modifications are possible. Note that the effects described herein are mere examples, and the effects of the present disclosure are not limited to the effects described herein. The present disclosure may have other effects than those described herein.

In addition, the present disclosure may take, for example, the following configurations.

(1)

An organic electroluminescence element including:

an anode, a light emitting layer and a cathode in this order; and

a low refractive index layer lower in refractive index than the light emitting layer at at least one of a position between the light emitting layer and the cathode and a position between the anode and the light emitting layer.

(2)

The organic electroluminescence element as described in the above paragraph (1),

in which the low refractive index layer is disposed between the light emitting layer and the cathode, and is configured using a material which has an electron transporting property or an electron injecting property.

(3)

The organic electroluminescence element as described in the above paragraph (1),

in which the low refractive index layer is disposed between the anode and the light emitting layer, and is configured using a material which has a hole injecting property or a hole transporting property.

(4)

The organic electroluminescence element as described in the above paragraph (2) or (3),

in which the low refractive index layer is configured using a material having a refractive index of more than 0.3 and less than 1.7.

(5)

The organic electroluminescence element as described in the above paragraph (3),

in which the low refractive index layer is configured using a material having a refractive index of 0.75 to 1.4.

(6)

The organic electroluminescence element as described in the above paragraph (2) or (3),

in which the low refractive index layer is configured using a material having a refractive index of 0.5 to 1.7.

(7)

The organic electroluminescence element as described in the above paragraph (3),

in which the low refractive index layer is configured using a material having a refractive index of 0.5 to 1.5.

(8)

An organic electroluminescence panel including:

a plurality of pixels,

in which each of the pixels has an organic electroluminescence element, and the organic electroluminescence element includes
an anode, a light emitting layer and a cathode in this order, and
a low refractive index layer lower in refractive index than the light emitting layer at at least one of a position between the light emitting layer and the cathode and a position between the anode and the light emitting layer.

(9)

The organic electroluminescence panel as described in the above paragraph (8),
in which the low refractive index layer is shared by the pixels.

(10)

An electronic apparatus including:

an organic electroluminescence panel; and

a driving circuit that drives the organic electroluminescence panel, in which the organic electroluminescence panel includes a plurality of pixels,

each of the pixels has an organic electroluminescence element, and

the organic electroluminescence element includes
an anode, a light emitting layer and a cathode in this order, and
a low refractive index layer lower in refractive index than the light emitting layer at at least one of a position between the light emitting layer and the cathode and a position between the anode and the light emitting layer.

What is claimed is:

1. An organic electroluminescence element comprising:
an anode, a light emitting layer and a cathode in this order; and
a low refractive index layer lower in refractive index than the light emitting layer at at least one of a position between the light emitting layer and the cathode and a position between the anode and the light emitting layer.

2. The organic electroluminescence element according to claim 1,
wherein the low refractive index layer is disposed between the light emitting layer and the cathode, and is configured using a material which has an electron transporting property or an electron injecting property.

3. The organic electroluminescence element according to claim 2,
wherein the low refractive index layer is configured using a material having a refractive index of more than 0.3 and less than 1.7.

4. The organic electroluminescence element according to claim 2,
wherein the low refractive index layer is configured using a material having a refractive index of 0.5 to 1.7.

5. An organic electroluminescence panel comprising:
a plurality of pixels,
wherein each of the pixels has an organic electroluminescence element, and
the organic electroluminescence element includes
an anode, a light emitting layer and a cathode in this order, and
a low refractive index layer lower in refractive index than the light emitting layer at at least one of a position between the light emitting layer and the cathode and a position between the anode and the light emitting layer.

6. The organic electroluminescence panel according to claim 5,
wherein the low refractive index layer is shared by the pixels.

7. An electronic apparatus comprising:
an organic electroluminescence panel; and
a driving circuit that drives the organic electroluminescence panel,
wherein the organic electroluminescence panel includes a plurality of pixels,
each of the pixels has an organic electroluminescence element, and
the organic electroluminescence element includes
an anode, a light emitting layer and a cathode in this order, and
a low refractive index layer lower in refractive index than the light emitting layer at at least one of a position between the light emitting layer and the cathode and a position between the anode and the light emitting layer.
